(19) United States
(12) Patent Application Publication
(10) Pub. No.: US 2012/0293397 A1
(43) Pub. Date: Nov. 22, 2012

(54) BOOTSTRAP CIRCUIT, INVERTER CIRCUIT, SCANNING CIRCUIT, DISPLAY DEVICE, AND ELECTRONIC APPARATUS

(75) Inventors: Satoshi Tatara, Kanagawa (JP); Katsuhide Uchino, Kanagawa (JP)

(73) Assignee: Sony Corporation, Tokyo (JP)

(21) Appl. No.: 13/460,150

(22) Filed: Apr. 30, 2012

(30) Foreign Application Priority Data
May 20, 2011 (JP) 2011-113047

(51) Int. Cl. G09G 3/20; H03K 3/00

(52) U.S. Cl. 345/55; 327/108

(57) ABSTRACT

Disclosed herein is a bootstrap circuit including: a transistor; and a capacitor connected between a gate electrode of the transistor, and one of source and drain regions of the transistor, the bootstrap circuit serving to carry out a bootstrap operation in which an electric potential at the gate electrode is changed depending on a change in an electric potential at the one of the source and drain regions, in which the transistor has a structure in which the source region and the drain region have a structure of being asymmetric with respect to a line passing through a center of the gate electrode.

### BACKGROUND

The present disclosure relates to a bootstrap circuit, an inverter circuit using the bootstrap circuit, a scanning circuit using the inverter circuit, a display device using the scanning circuit, and an electronic apparatus including the display device.

A bootstrap circuit is a circuit which includes a transistor and a capacitor connected between a gate electrode and one of source and drain regions of the transistor, and which carries out a bootstrap operation in which an electric potential of the gate electrode is changed depending on a change in an electric potential of the one of the source and drain regions. The bootstrap circuit is generally used in various kinds of electronic circuits. An inverter circuit utilizing the bootstrap operation is known as an example of the electronic circuit using the bootstrap circuit. The inverter circuit, for example, is disclosed in Japanese Patent Laid-Open No. 2009-188749.

### SUMMARY

In the bootstrap circuit, a ratio (=ΔV_{g}/ΔVₛ) of a variation ΔV_{g} of an electric potential at a gate electrode to a variation ΔVₛ of an electric potential at one of source and drain electrodes of a transistor becomes a bootstrap gain G_{BST}. For the bootstrap gain G_{BST}, 1 (100%) is an ideal value. However, various kinds of parasitic capacitances are parasitic in a gate node (gate electrode) of the transistor depending on circuit configurations. Also, the presence of these parasitic capacitances results in a reduction in the bootstrap gain G_{BST}.

The present disclosure has been made in order to solve the problems described above, and it is therefore desirable to provide a bootstrap circuit which enables a bootstrap gain to be increased, an inverter circuit using the bootstrap circuit, a scanning circuit using the inverter circuit, a display device using the scanning circuit, and an electronic apparatus including the display device.

In order to attain the desire described above, according to an embodiment of the present disclosure, there is provided a bootstrap circuit including: a transistor; and a capacitor connected between a gate electrode of the transistor, and one of source and drain regions of the transistor, the bootstrap circuit serving to carry out a bootstrap operation in which an electric potential at the gate electrode is changed depending on a change in an electric potential at the one of the source and drain regions, in which the transistor has a structure in which the source region and the drain region have a structure of being asymmetric with respect to a line passing through a center of the gate electrode.

In the bootstrap circuit, the transistor serving to carry out the bootstrap operation has the structure in which the source region and the drain region are asymmetric with respect to the line passing through the center of the gate electrode. Therefore, an amount of overlap between the gate electrode and the source region, and an amount of overlap between the gate electrode and the drain region are different from each other. As a result, with regard to parasitic capacitances parasitic between the gate electrode, and the source and drain regions, a capacitance value of the parasitic capacitance corresponding to a smaller amount of overlap becomes smaller than that of the parasitic capacitance corresponding to a larger amount of overlap. Also, one of the source and drain regions corresponding to the smaller amount of overlap is used as one of the source and drain regions to which no capacitor is connected, whereby the parasitic capacitance on the side of the one of the source and drain regions acts on a direction of increasing the bootstrap gain. As a result, the bootstrap gain is increased.

An inverter circuit can be configured by using the bootstrap circuit.

According to another embodiment of the present disclosure, there is provided an inverter circuit including: a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions; and a second transistor having the same conductivity type as that of the first transistor and connected in series with the first transistor, in which the first transistor has a structure in which the source region and the drain region have a structure of being asymmetric with respect to a line passing through a center of the gate electrode; and a polarity of a signal inputted to the gate electrode of the second transistor is inverted and a resulting signal having an inverted polarity is outputted.

A scanning circuit can be configured by using the inverter circuit.

According to still another embodiment of the present disclosure, there is provided a scanning circuit including: an inverter circuit, the inverter circuit including: a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions; and a second transistor having the same conductivity type as that of the first transistor and connected in series with the first transistor, in which the first transistor has a structure in which the source region and the drain region have a structure of being asymmetric with respect to a line passing through a center of the gate electrode; and a polarity of a signal inputted to the gate electrode of the second transistor is inverted and a resulting signal having an inverted polarity is outputted.

A display device can be configured by using the scanning circuit.

According to yet another embodiment of the present disclosure, there is provided a display device including: a pixel array portion in which pixels each including an electrooptic element are disposed in a matrix; and a scanning circuit scanning the pixels of the pixel array portion, the scanning circuit including: an inverter circuit, the inverter circuit including: a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions; and a second transistor having the same conductivity type as that of the first transistor and connected in series with the first transistor, in which the transistor has a structure in which the source region and the drain region have a structure of being asymmetric with respect to a line passing through a center of the gate electrode; and a polarity of a signal inputted to the gate electrode of the second transistor is inverted and a resulting signal having an inverted polarity is outputted.

According to a further embodiment of the present disclosure, there is provided a display device including: a pixel array portion in which pixels each including an electrooptic element are disposed in a matrix; and a scanning circuit scanning the pixels of the pixel array portion, in which each of the pixels includes: a drive transistor driving corresponding one of the electrooptic elements; and a capacitor connected between a gate electrode of the drive transistor, and one of source and drain regions of the drive transistor; and the drive transistor has a structure in which the source region and the drain region have a structure of being asymmetric with respect to a line passing through a center of the gate electrode, and serves to carry out a bootstrap operation in which an electric potential at the gate electrode is changed depending on a change in an electric potential at the one of the source region and the drain region.

The display devices described above can be used as display portions of various kinds of electronic apparatuses.

According to an even further embodiment of the present disclosure, there is provided an electronic apparatus including: a display device, the display device including: a pixel array portion in which pixels each including an electrooptic element are disposed in a matrix; and a scanning circuit scanning the pixels of the pixel array portion, the scanning circuit including: a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions; and a second transistor having the same conductivity type as that of the first transistor and connected in series with the first transistor, in which the transistor has a structure in which the source region and the drain region have a structure of being asymmetric with respect to a line passing through a center of the gate electrode; and a polarity of a signal inputted to the gate electrode of the second transistor is inverted and a resulting signal having an inverted polarity is outputted.

According to a still further embodiment of the present disclosure, there is provided an electronic apparatus including: a display device, the display device including: a pixel array portion in which pixels each including an electrooptic element are disposed in a matrix; and a scanning circuit scanning the pixels of the pixel array portion, in which each of the pixels includes: a drive transistor driving corresponding one of the electrooptic elements; and a capacitor connected between a gate electrode of the drive transistor, and one of source and drain regions of the drive transistor; and the drive transistor has a structure in which the source region and the drain region have a structure of being asymmetric with respect to a line passing through a center of the gate electrode, and serves to carry out a bootstrap operation in which an electric potential at the gate electrode is changed depending on a change in an electric potential at the one of the source region and the drain region.

As set forth hereinabove, according to the present disclosure, the transistor composing the bootstrap circuit adopts the structure in which the source region and the drain region are asymmetric with respect to the line passing through the center of the gate electrode. As a result, it becomes possible to increase the bootstrap gain.

### BRIEF DESCRIPTION OF THE DRAWINGS

FIG. 1 is a circuit diagram showing an outline of a circuit configuration of an inverter circuit to which the present disclosure is applied;

FIG. 2 is a timing waveform chart showing signal waveforms of respective portions in an inverter circuit in an N-th stage;

FIG. 3 is a circuit diagram explaining parasitic capacitances parasitic in an input node of a bootstrap circuit;

FIG. 4 is a planar pattern view showing a relationship between a source region and a drain region of a transistor for carrying out a bootstrap operation;

FIG. 5 is a circuit diagram showing a configuration of an inverter circuit according to a first embodiment of the present disclosure;

FIG. 6 is a system configuration diagram showing an outline of a basic configuration of an active matrix type organic EL (electroluminescence) display device to which the present disclosure is applied;

FIG. 7 is a circuit diagram showing a circuit configuration of a pixel (pixel circuit) in the active matrix type organic EL display device shown in FIG. 6;

FIG. 8 is a timing waveform chart explaining a basic circuit operation of an organic EL display device to which the present disclosure is applied;

FIGS. 9A to 9H are respectively operation explanatory diagrams explaining the basic circuit operation of the organic EL display device to which the present disclosure is applied;

FIGS. 10A and 10B are respectively a graphical representation explaining a problem due to a dispersion of threshold voltages of thin film transistors, and a graphical representation explaining a problem due to a dispersion of mobilities of drive transistors;

FIGS. 11A and 11B are respectively a circuit diagram showing a circuit configuration of a write scanning circuit, and a circuit diagram showing a circuit configuration of a power source supply scanning circuit;

FIG. 12 is a perspective view showing an external appearance of a television set as a first example of application to which the organic EL display device of the fourth embodiment is applied;

FIGS. 13A and 13B are respectively a perspective view showing an external appearance of a digital camera as a second example of application, when viewed from a front side, to which the organic EL display device of the fourth embodiment is applied, and a perspective view of the digital camera as the second example of application, when viewed from a back side, to which the organic EL display device of the fourth embodiment is applied;

FIG. 14 is a perspective view showing an external appearance of a notebook-size personal computer as a third example of application to which the organic EL display device of the fourth embodiment is applied;

FIG. 15 is a perspective view showing an external appearance of a video camera as a fourth example of application to which the organic EL display device of the fourth embodiment is applied; and

FIGS. 16A to 16G are respectively a front view of a mobile phone as a fifth example of application, in an open state, to which the organic EL display device of the fourth embodiment is applied, a side elevational view thereof in the open state, a front view thereof in a close state, a left side elevational view thereof in the close state, a right side elevational view thereof in the close state, a top plan view thereof in the close state, and a bottom view thereof in the close state.

### DETAILED DESCRIPTION OF THE PREFERRED EMBODIMENTS

Embodiments of the present disclosure will be described in detail hereinafter with reference to the accompanying drawings. It is noted that the description will be given below in accordance with the following order:

### 1. Outline of Inverter Circuit to Which the Present Disclosure is Applied;

### 1-1. Circuit Configuration

### 1-2. Circuit Operation

### 1-3. Nonconformity due to Parasitic Capacitances

### 2. Inverter Circuit, Bootstrap Circuit, and Scanning Circuit;

### 2-1. Transistor Structure

### 2-2. Circuit Configuration of Inverter Circuit (First Embodiment)

### 2-3. Bootstrap Circuit (Second Embodiment)

### 2-4. Scanning Circuit (Third Embodiment)

### 3. Outline of Display Device to Which the Present Disclosure is Applied;

### 3-1. System Configuration

### 3-2. Basic Circuit Operation

3-3. Display Device having Application to Pixel Circuit (Fourth Embodiment)
3-4. Display Device having Application to Scanning Circuit (Fifth Embodiment)

### 3-5. Modified Changes

### 4. Electronic Apparatus; and

### 4-1. Electronic Apparatus (Sixth Embodiment)

### 4-2. Electronic Apparatus (Seventh Embodiment)

### 4-3. Examples of Application

### 5. Constitutions of the Present Disclosure.

### 1. Outline of Inverter Circuit to Which the Present Disclosure is Applied

### [1-1. Circuit Configuration]

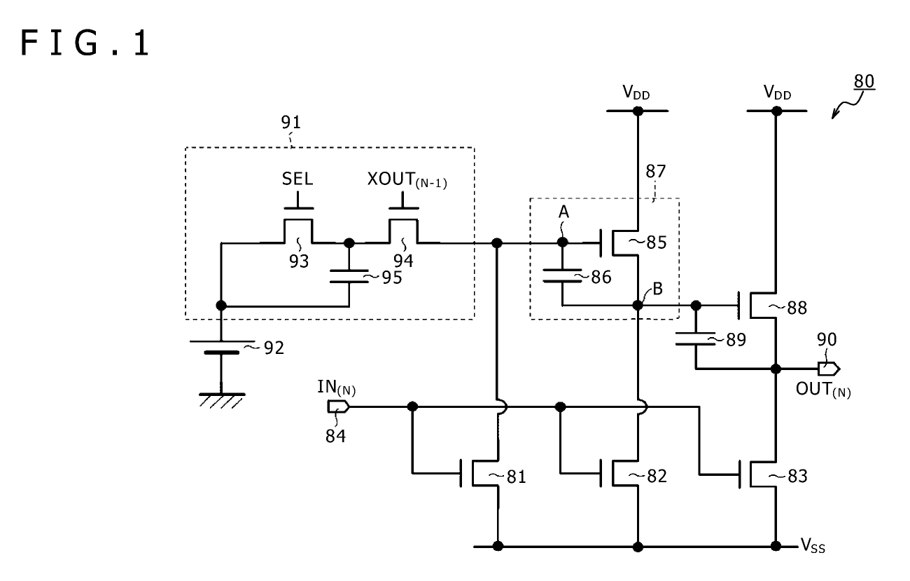

FIG. 1 is a circuit diagram showing a circuit configuration of an inverter circuit to which the present disclosure is applied. As shown in FIG. 1, the inverter circuit 80 has a circuit configuration using transistors having the same conductivity type, that is, transistors having one type channels.

A Thin Film Transistor (TFT), for example, can be used as the transistor composing the inverter circuit 80. In addition, in this case, an N-channel transistor shall be used. Therefore, in the following description, a source/drain electrode (region) on a positive power source V_{DD} side of the transistor will be referred to as a drain electrode (region), and the source/drain electrode (region) on a negative power source V_{SS} side of the transistor will be referred to as a source electrode (region).

When the inverter circuit is configured by using transistors having one type channels (either only the N-channels or only the P-channels), the manufacturing cost can be reduced as compared with the case where the inverter circuit is configured by using transistors having two type channels. In addition, when the inverter circuit is configured by using the transistors having one type channels, for the purpose of ensuring a circuit operation of the inverter circuit, there is adopted a circuit configuration based on a combination of transistors having one type channels, and capacitors.

Referring to FIG. 1, for example, each of gate electrodes of three transistors 81, 82, and 83 is connected to a circuit input terminal 84, and each of source electrodes thereof is connected to a negative power source V_{SS}. A drain electrode of the transistor 81 is connected to a gate electrode of a transistor 85. A drain electrode of the transistor 85 is connected to a positive power source V_{DD}, and a source electrode thereof is connected to a drain electrode of the transistor 82. That is to say, the transistor 85 and the transistor 82 have a configuration of being connected in series between the positive power source V_{DD} and the negative power source V_{SS}.

A capacitor 86 is connected between the gate electrode and the source electrode of the transistor 85. The transistor 85 configures, together with the capacitor 86 connected between the gate electrode and the source electrode of the transistor 85, a bootstrap circuit 87. The bootstrap circuit 87 carries out a bootstrap operation in which an electric potential at the gate electrode (that is, a gate electric potential) is changed depending on a change at the source electrode (source region) (that is, a source electric potential) of the transistor 85.

A gate electrode of the transistor 88 is connected to the source electrode of the transistor 85 as an output node B of the bootstrap circuit 87. A drain electrode of the transistor 88 is connected to the positive power source V_{DD}, and a source electrode thereof is connected to the drain electrode of the transistor 83. That is to say, both of the transistor 88 and the transistor 83 have a configuration of being connected in series between the positive power source V_{DD} and the negative power source V_{SS}. A capacitor 89 is connected between the gate electrode and the source electrode of the transistor 88. Also, a source node of the transistor 88 becomes an output node of the inverter circuit 80, and is connected to a circuit output terminal 90.

A voltage setting portion 91 for setting a gate-to-source voltage of the transistor 85 to a predetermined voltage prior to the carrying-out of the bootstrap operation is connected to the gate electrode of the transistor 85 as an input node A of the bootstrap circuit 87. The voltage setting portion 91 is composed of transistors 93 and 94 connected in series between a fixed power source 92 which outputs a given voltage, and the gate electrode of the transistor 85, and a capacitor 95 connected in parallel with the transistor 93.

The inverter circuit 80 having the configuration described above, for example, can be used as an inverter circuit which is disposed in a subsequent stage of each of shift stages (transfer stages) of a shift register in a scanning circuit configured by using the shift register. When the inverter circuit 80 is used in the scanning circuit, the inverter circuit 80 shown in FIG. 1 is an inverter circuit in an N-th stage disposed in a subsequent stage of a shift stage in the N-th stage. Also, an inverted output signal XOUT_{(N-1)} of an output signal OUT_{(N-1)} from a shift stage in an (N−1)-th stage is inputted to a gate electrode of the transistor 94 of the voltage setting portion 91. On the other hand, a selection signal SEL is inputted to a gate electrode of the transistor 93 at a predetermined timing.

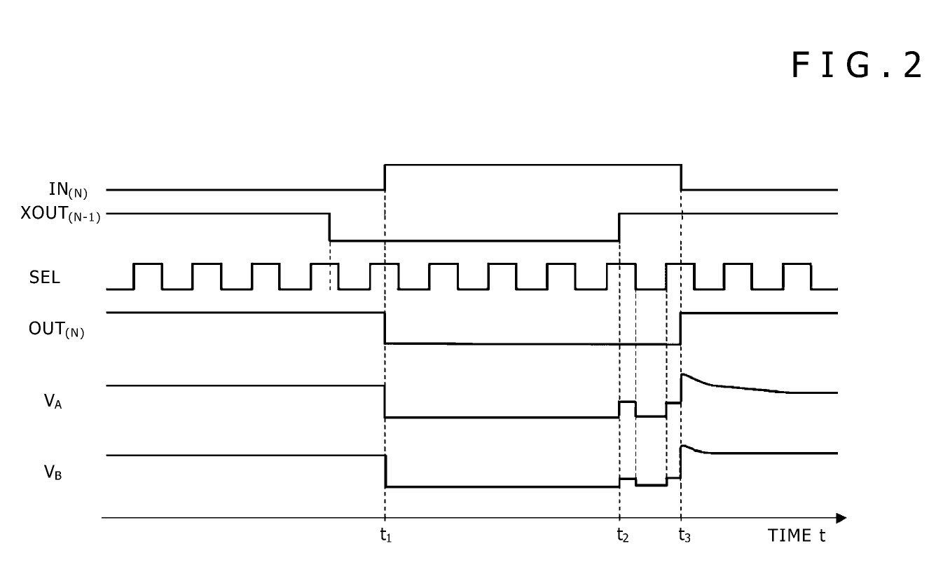

FIG. 2 is a timing waveform chart showing signal waveforms of respective portions in the inverter circuit 80 in the N-th stage. That is to say, FIG. 2 shows the waveforms of an input signal IN_{(N)} in the N-th stage, the inverted output signal XOUT_{(N-1)} from the shift stage in the (N−1)-th stage, the selection signal SEL, an output signal OUT_{(N)} in the N-th stage, an electric potential V_{A} at the input node A of the bootstrap circuit 87, and an electric potential V_{B} at the output node B.

### [1-2. Circuit Operation]

Subsequently, in the inverter circuit 80 having the configuration described above, a circuit operation when the input signal IN_{(N)} inputted through a circuit input terminal 84 becomes an active state (a high level in this case), and a circuit operation when the input signal IN_{(N)} inputted through the circuit input terminal 84 becomes a non-active state (a low level in this case) will be described with reference to the timing waveform charts of FIG. 2. Here, the high level means a level (electric potential) of the positive power source V_{DD}, and the low level means a level (electric potential) of the negative power source V_{SS}.

### (When Input Signal IN_{(N)} Becomes Active State)

When the input signal IN_{(N)} transits from the low level to the high level at a time t₁, each of the three transistors 81, 82, and 83 on the negative power source V_{SS} side becomes a conductive state. The transistor 83 becomes the conduction state, whereby the output signal OUT_{(N)} derived from a circuit output terminal 90 becomes the low level (that is, the V_{SS} level). In addition, each of the transistors 81 and 82 becomes the conduction state, whereby each of the electric potentials at the input node A and the output node B is fixed to the negative power source electric potential V_{SS}. As a result, each of the two transistors 85 and 88 on the positive power source V_{DD} side becomes a non-conduction state.

When the inverted output signal XOUT_{(N-1)} in the shift stage in the (N−1)-th stage transits from the low level to the high level at a time t₂ in this case, the transistor 94 of the voltage setting portion 91 becomes the conduction state. Therefore, a predetermined voltage held in the capacitor 95 is supplied to the gate electrode of the transistor 85. It is noted that a voltage of the fixed power source 92 is held in the capacitor 95 under the drive by the transistor 93 based on the selection signal SEL in the voltage setting portion 91. Therefore, the predetermined voltage supplied to the gate electrode of the transistor 85 is the voltage of the fixed power source 92.

Also, the predetermined voltage, that is, the voltage of the fixed power source 92 is supplied to the gate electrode of the transistor 85, whereby the transistor 85 becomes the conduction state. As a result, a through current is caused to flow from the positive power source V_{DD} toward the negative power source V_{SS}. It is noted that the voltage supplied from the voltage setting portion 91 to the gate electrode of the transistor 85 is held in the capacitor 86.

### (When Input Signal IN_{(N)} Becomes Non-Active State)

Next, when the input signal IN_{(N)} transits from the high level to the low level at a time t₃, each of the three transistors 81, 82, and 83 on the negative power source V_{SS} side becomes the non-conduction state. At this time, since the predetermined voltage supplied from the voltage setting portion 91 is held in the capacitor 86, the transistor 85 becomes the conduction state.

Also, the electric potential at the output node B rises, whereby the gate-to-source voltage of the transistor 88 becomes large. Therefore, the transistor 88 in the output stage also becomes the conduction state so as to follow the conduction state of the transistor 85 in the first stage. As a result, the output signal OUT_{(N)} derived from the circuit output terminal 90 becomes the high level (that is, the V_{DD} level).

In addition, the bootstrap operation in which the gate electric potential, that is, the electric potential at the output node A rises (is changed) in accordance with a rise (change) in the electric potential at the output node B, that is, the source electric potential is carried out in the transistor 85 in the first stage composing the bootstrap circuit 87. Since the gate-to-source voltage of the transistor 85 is held by carrying out the bootstrap operation, the transistor 85 continues to maintain the conduction state.

### [1-3. Nonconformity Due to Parasitic Capacitances]

Now, in the bootstrap circuit 87, a ratio (=ΔV_{A}/ΔV_{B}) of a variation ΔV_{A} in the gate electric potential, that is, the electric potential V_{A} at the input node A to a variation (rise amount) ΔV_{B} in the source electric potential of the transistor 85, that is, the electric potential V_{B} at the output node B becomes a bootstrap gain G_{BST}. For the bootstrap gain G_{BST}, 1 (100%) is an ideal value.

However, various kinds of parasitic capacitances are parasitic in the input node A of the boosting circuit 87. In the case of the circuit configuration of the inverter circuit 80, the parasitic capacitances parasitic in the input node A of the boosting circuit 87 include a parasitic capacitance parasitic between the gate electrode and the drain electrode of the transistor 85, a parasitic capacitance parasitic between the gate electrode and the source electrode of the transistor 85, a parasitic capacitance parasitic between the gate electrode and the drain electrode of the transistor 81, a parasitic capacitance parasitic between the gate electrode and the source electrode of the transistor 94, and the like. Also, in addition to those parasitic capacitances, the capacitor 86 is connected to the input node A.

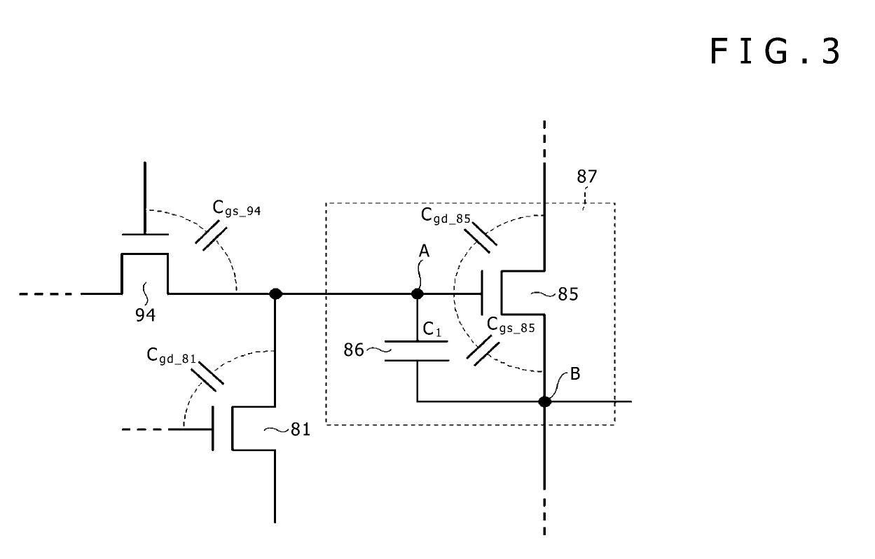

Here, as shown in FIG. 3, let C_{gd}_{_{—}}₈₅ be a capacitance value of the parasitic capacitance between the gate electrode and the drain electrode of the transistor 85, let C_{gs}_{_{—}}₈₅ be a capacitance value of the parasitic capacitance between the gate electrode and the source electrode of the transistor 85, and let C₁ be a capacitance value of the capacitor 86 between the gate electrode and the source electrode of the transistor 85. In addition, let C_{gd}_{_{—}}₈₁ be a capacitance value of the parasitic capacitance between the gate electrode and the drain electrode of the transistor 81 which is connected to the input node A, and let C_{gs}_{_{—}}₉₄ be a capacitance value of the parasitic capacitance between the gate electrode and the source electrode of the transistor 94 which is also connected to the input node A.

At this time, the bootstrap gain G_{BST} of the bootstrap circuit 87 is given by Expression (1):

G_{BST}=(C_{gs}_{_{—}}₈₅+C₁)/(C_{gs}_{_{—}}₈₅+C₁+C_{gd}_{_{—}}₈₅+C_{gd}_{_{—}}₈₁+C_{gs}_{_{—}}₉₄) (1)

As apparent from Expression (1), when the capacitance value of the parasitic capacitance parasitic in the input node A of the bootstrap circuit 87, especially, the capacitance value of the parasitic capacitance existing in only a denominator side of Expression (1) is large, the bootstrap gain G_{BST} is reduced.

Also, if the bootstrap gain G_{BST} is low, when the input signal IN_{(N)} becomes the non-active state, that is, when the input signal IN_{(N)} transits from the high level to the low level, a rise amount ΔV_{A} of the electric potential V_{A} at the input node A becomes small. Also, when the rise amount ΔV_{A} of the electric potential V_{A} at the input node A becomes small, it is difficult to derive a signal having a full amplitude, that is, an amplitude of (V_{SS}−V_{DD}) as the output signal OUT_{(N)} for a long period of time.

In the foregoing, the nonconformity due to the parasitic capacitances parasitic in the input node A of the bootstrap circuit 87 has been described by exemplifying the inverter circuit 80 using the bootstrap circuit 87. However, this also applies to the case of the bootstrap circuit 87 itself.

### 2. Inverter Circuit, Bootstrap Circuit, and Scanning Circuit

In an inverter circuit according to a first embodiment of the present disclosure, in a bootstrap circuit including a transistor, and a capacitor connected between a gate electrode and a source/drain region of the transistor, the feature of the transistor is to adopt the following structure. That is to say, with regard to the transistor for carrying out the bootstrap operation, the source region and the drain region have a structure of being asymmetric with respect to a line passing through a center of the gate electrode. Here, “an asymmetric structure” includes the case where liquid crystal molecules have substantially an asymmetric structure in addition to the case where an asymmetric structure is obtained in a narrow sense. In other words, the presence of various kinds of dispersions caused in terms of a design or manufacture is allowed.

### [2-1. Transistor Structure]

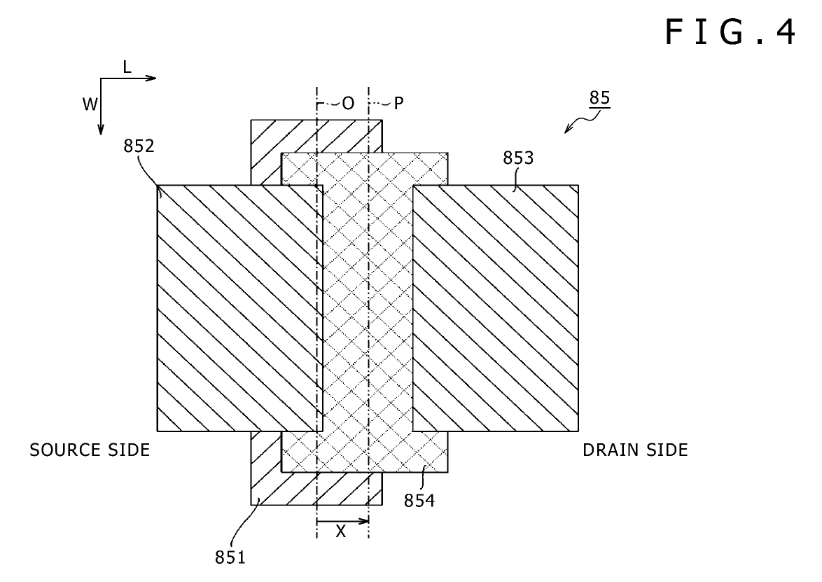

A structure of the transistor for carrying out the bootstrap operation will now be more concretely described with reference to a planar pattern view of FIG. 4, that is, a planar pattern view showing a relationship between the source region and the drain region.

As shown in FIG. 4, with regard to the transistor (for example, a TFT) 85 for carrying out the bootstrap operation, a source region 852 and a drain region 853 have a structure of being asymmetric with respect to a center of a gate electrode 851, more specifically, a line (central line) O passing through a center in a direction of a channel length L. In this case shown in FIG. 4, about half the source region 852 overlaps the gate electrode 851, whereas the drain region 853 does not overlap the gate electrode 851 at all. It is noted that an insulating film 854 is interposed between a semiconductor layer including both of the source region 852 and the drain region 853, and the gate electrode 851.

In general, the source region 852 and the drain region 853 are formed so as to have the same size. Also, the source region 852 and the drain region 853 have a structure of being symmetric with respect to a central line P extending between the source region 852 and the drain region 853. In the normal transistor having such a symmetric structure, the central line O of the gate electrode 851, and the central line P extending between the source region 852 and the drain region 853 agree with each other. Also, an amount of overlap between the gate electrode 851 and the source region 852, and an amount of overlap between the gate electrode 851 and the drain region 853 are approximately equal to each other.

On the other hand, in the transistor structure in the inverter circuit of the first embodiment, the source region 852 and the drain region 853 have the structure of being asymmetric with respect to the central line O of the gate electrode 851. Therefore, the central line P extending between the source region 852 and the drain region 853 is out of the central line O of the gate electrode 851. At this time, the central line P is shifted in a direction in which the amount of overlap between the gate electrode 851 and the drain region 853 becomes smaller than that of overlap between the gate electrode 851 and the source region 852.

That is to say, the source region 852 and the drain region 853 have the structure of being asymmetric with respect to the central line O of the gate electrode 851, which results in that the amount of overlap between the gate electrode 851 and the source region 852, and the amount of overlap between the gate electrode 851 and the drain region 853 become different from each other. In the transistor 85 of the inverter circuit of the first embodiment, the amount of overlap between the gate electrode 851 and the drain region 853 becomes smaller than that of overlap between the gate electrode 851 and the source region 852.

As a result, with regard to the parasitic capacitance parasitic between the gate electrode 851, and the source region 852/the drain region 853, a capacitance value of the parasitic capacitance corresponding to the smaller amount of overlap becomes smaller than that of the parasitic capacitance corresponding to the larger amount of overlap. Specifically, the capacitance value of the parasitic capacitance parasitic between the gate electrode 851 and the drain region 853 becomes smaller than that of the parasitic capacitance parasitic between the gate electrode 851 and the source region 852.

The amounts of overlap at this time are determined depending on a shift amount X of central line P with respect to the central line O. The transistor 85 of the inverter circuit of the first embodiment shows a shift amount X by which the drain region 853 does not overlap the gate electrode 851 at all. That is to say, since the drain region 853 does not overlap the gate electrode 851 at all, namely, the amount of overlap between them is zero, the parasitic capacitance is not parasitic between the gate electrode 851 and the drain region 853, that is, the capacitance value of the parasitic capacitance becomes zero.

Here, for example, the drain region 853 whose amount of overlap with the gate electrode 851 is smaller than that of overlap between the gate electrode 851 and the source region 852 is set as a region on the side to which the capacitor 86 is not connected. Then, since the capacitance value C_{gd}_{_{—}}₈₅ of the parasitic capacitance parasitic in the drain region 853 side becomes the capacitance value on the denominator side in Expression (1) described above, the parasitic capacitance concerned acts on a direction of increasing the bootstrap gain G_{BST}. As a result, since the amount of rise (the amount of change) of the electric potential at the input node A of the boosting circuit 87, it becomes possible to output the signal having the full amplitude over a long period of time.

### [2-2. Circuit Configuration of Inverter Circuit]

Hereinafter, a circuit configuration of the inverter circuit 80 according to the first embodiment of the present disclosure which is applied to the inverter circuit 80 having the one type channels previously described with reference to FIG. 1 will be described in detail.

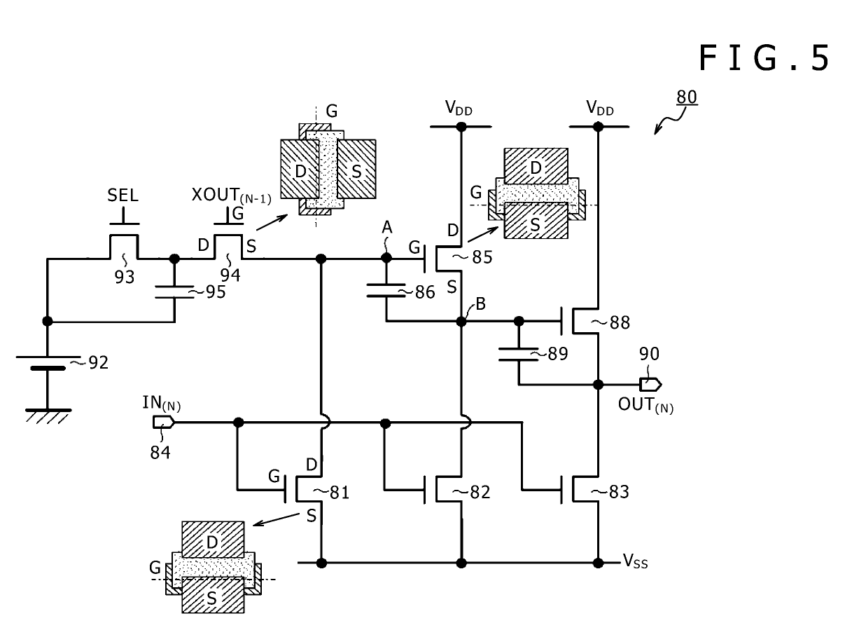

FIG. 5 is a circuit diagram showing a configuration of the inverter circuit 80 according to the first embodiment of the present disclosure. The configuration of the inverter circuit 80 of the first embodiment is the same as that of the inverter circuit 80 shown in FIG. 1. Therefore, the same portions as those shown in FIG. 1 are designated by the same reference numerals or symbols, respectively. Thus, since a detailed description of the circuit configuration is repeated, it is omitted here for the sake of simplicity.

In the inverter circuit 80 of the first embodiment, as previously stated, the parasitic capacitance (C_{gs}_{_{—}}₈₅) between the gate electrode and the source region, and the parasitic capacitance (C_{gd}_{_{—}}₈₅) between the gate electrode and the drain region are both parasitic in the input node A of the bootstrap circuit 87, that is, the gate electrode of the transistor 85. In addition to those parasitic capacitances (C_{gs}_{_{—}}₈₅ and C_{gd}_{_{—}}₈₅), the capacitor 86 is also connected to the gate electrode of the transistor 85.

In the inverter circuit 80 of the first embodiment, the structure in which, as shown in FIG. 4, the source region 852 and the drain region 853 are asymmetric with respect to the central line O of the gate electrode 851 is applied to the transistor 85. More specifically, an asymmetric structure is adopted such that the amount of overlap between the gate electrode 851 and the drain region 853 becomes smaller than that of overlap between the gate electrode 851 and the source region 852.

As a result, with regard to the parasitic capacitance parasitic between the gate electrode 851, and the source region 852/the drain region 853, the capacitance value C_{gd}_{_{—}}₈₅ of the parasitic capacitance on the drain region 853 side having the smaller amount of overlap becomes smaller than the capacitance value C_{gs}_{_{—}}₈₅ of the parasitic capacitance on the drain region 852 side having the larger amount of overlap. In the case of the inverter circuit 80 shown in FIG. 4, since the amount of overlap between the gate electrode 851 and the drain region 853 is zero, the capacitance value C_{gd}_{_{—}}₈₅ of the parasitic capacitance on the drain region 853 side becomes zero.

Therefore, as apparent from Expression (1) described above, the bootstrap gain G_{BST} is increased by the capacitance value by which the capacitance value C_{gd}_{_{—}}₈₅ of the parasitic capacitance on the drain region 853 side can be cut down. Since the increase in the bootstrap gain G_{BST} results in that a rise amount of electric potential at the input node A of the bootstrap circuit 87 is increased, it becomes possible to output the signal having the full amplitude over a long period of time.

As previously stated, both of the drain electrode (region) of the transistor 81, and the source electrode (region) of the transistor 94 are connected to the gate electrode of the transistor 85. As a result, in addition to the parasitic capacitances (C_{gs}_{_{—}}₈₈ and C_{gd}_{_{—}}₈₅), and the capacitor 86, both of a parasitic capacitance (C_{gd}_{_{—}}₈₁) between the gate electrode and the drain region of the transistor 81, and a parasitic capacitance (C_{gs}_{_{—}}₉₄) between the gate electrode and the source region of the transistor 94 are parasitic in the gate electrode of the transistor 85.

In order to cope with such a situation, the asymmetric structure described above, that is, the structure in which the source region and the drain region are asymmetric with respect to the central line O of the gate electrode (refer to FIG. 4) is applied to at least one of, preferably, both of the transistor 81 and the transistor 94. Specifically, with regard to the transistor 81, an asymmetric structure is adopted such that the amount of overlap between the gate electrode and the drain region becomes smaller than that of overlap between the gate electrode and the source region. In addition, with regard to the transistor 94, an asymmetric structure is adopted such that the amount of overlap between the gate electrode and the source region becomes smaller than that of overlap between the gate electrode and the drain region.

In such a way, with regard to the transistor 81, the amount of overlap between the gate electrode and the drain region is made smaller than that of overlap on the source side, preferably, made zero, whereby a capacitance value C_{gd}_{_{—}}₈₁ of the parasitic capacitance on the drain region side of the transistor 81 becomes zero. In addition, with regard to the transistor 94, the amount of overlap between the gate electrode and the source region is made smaller than that of overlap on the drain side, preferably, made zero, whereby a capacitance value C_{gd}_{_{—}}₉₄ of the parasitic capacitance on the source region of the transistor 94 becomes zero.

As a result, in Expression (1) described above, in addition to the capacitance value C_{gd}_{_{—}}₈₅ on the denominator side, both of the capacitance value C_{gd}_{_{—}}₈₁ and the capacitance value C_{gd}_{_{—}}₉₄ on the denominator side are also cut down. Therefore, the bootstrap gain G_{BST} is increased by the capacitance value thus cut down. As a result, the rise amount of electric potential at the input node A of the bootstrap circuit 87 becomes larger than that in the case where only the capacitance value C_{gd}_{_{—}}₈₅ is cut down. Therefore, it becomes possible to more reliably output the signal having the full amplitude over a long period of time.

### [2-3. Bootstrap Circuit]

The bootstrap circuit 87 according to a second embodiment of the present disclosure includes the transistor 85, and the capacitor 86 connected between the gate electrode of the transistor 85, and one of the source and drain regions of the transistor 85. In this case, the bootstrap circuit 87 serves to carry out the bootstrap operation in which the electric potential at the gate electrode is changed depending on the change in the electric potential at the one of the source and drain regions S and D. In addition, the transistor 85 has the structure in which the source region S and the drain region D have the structure of being asymmetric with respect to the central line O passing through the center of the gate electrode 851.

As described above, the inverter circuit 80 of the first embodiment uses (includes) the bootstrap circuit 87 of the second embodiment.

The bootstrap circuit 87 according to the second embodiment of the present disclosure which has been described so far can be used as a drive circuit (pixel circuit) for driving an electrooptic element which carries out the bootstrap operation in the pixel circuit of a display device. In addition, the inverter circuit 80 according to the first embodiment of the present disclosure using the bootstrap circuit 87 according to the second embodiment of the present disclosure can be used as an inverter circuit composing a scanning circuit of the display device.

### [2-4. Scanning Circuit]

A scanning circuit according to a third embodiment of the present disclosure includes (uses) the inverter circuit 80 of the first embodiment. As described above, the inverter circuit 80 includes the transistor 85 including the gate electrode, and the source and drain regions, and the transistor 82 having the same conductivity type as that of the transistor 85 and connected in series with the transistor 85. In this case, the capacitor 86 is connected between the gate electrode and the source region. Also, the transistor 85 carries out the bootstrap operation in which the electric potential at the gate electrode is changed depending on the change in the electric potential at the source region. In this case, the transistor 85 has the structure in which the source region and the drain region have the structure of being asymmetric with respect to the central line O passing through the center of the gate electrode, and the polarity of the signal IN_{(N)} inputted to the gate electrode of the transistor 82 is inverted and the resulting signal OUT_{(N)} having the inverted polarity is outputted. Hereinafter, a display device to which the present disclosure is applied will be described in detail

3. Outline of Display Device to which the Present Disclosure is Applied

### [3-1. System Configuration]

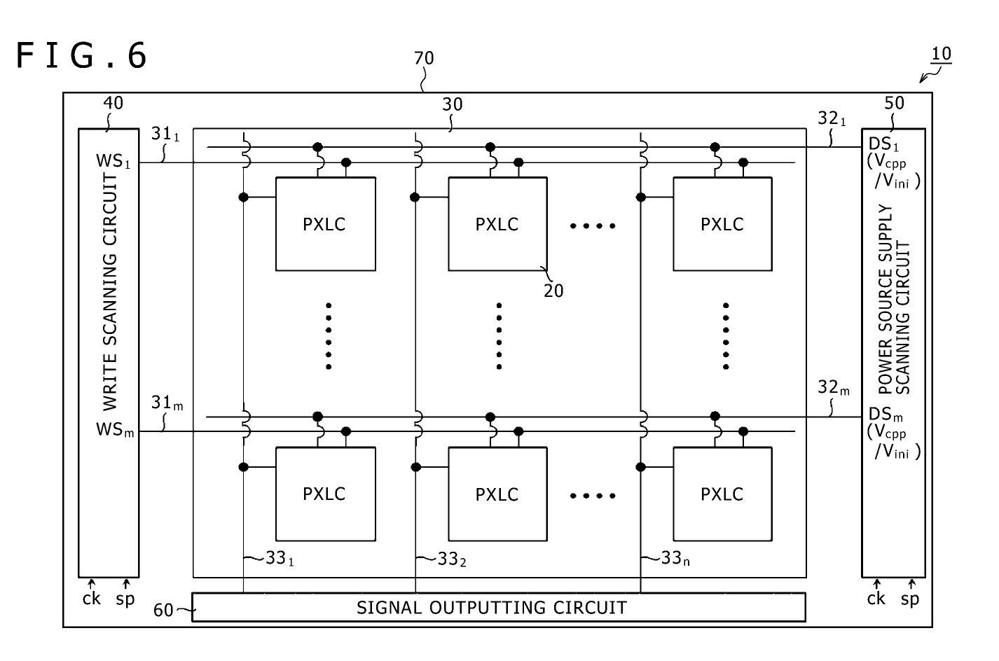

FIG. 6 is a schematic block diagram showing a basic system configuration of an active matrix type display device to which the present disclosure is applied.

The active matrix type display device is a display device in which a current caused to flow through an electrooptic element is controlled by an active element provided in the same pixel as that of the electrooptic element, for example, an insulated gate field-effect transistor. A Thin Film Transistor (TFT) is typically used as the insulated gate field-effect transistor.

In this case, as an example, a description will now be given by exemplifying the case of an active matrix type organic EL display device in which a current drive type electrooptic element whose emission luminance is changed in accordance with a value of a current caused to flow through a device, for example, an organic EL element is used as a light emitting element of a pixel (pixel circuit).

As shown in FIG. 6, an organic EL display device 10 as the display device to which the present disclosure is applied is configured so as to include plural pixels 20 each including an organic EL element, a pixel array portion 30, and a drive circuit portion. In this case, the pixels 20 are two-dimensionally disposed in a matrix in the pixel array portion 30. Also, the drive circuit portion is disposed in the periphery of the pixel array portion 30. In addition, the drive circuit portion is composed of a write scanning circuit 40, a power source supply scanning circuit 50, a signal outputting circuit 60, and the like, and drives each of the pixels 20 disposed in the pixel array portion 30.

Here, when the organic EL display device 10 is a display device compatible with color display, one pixel (unit pixel) becoming a unit forming a color image is composed of plural sub-pixels, and each of the sub-pixels corresponds to the pixel 20 shown in FIG. 6. More specifically, in the display device compatible with the color display, one pixel, for example, is composed of three sub-pixels: a sub-pixel for emitting a Red (R) color light; a sub-pixel for emitting a Green (G) color light; and a sub-pixel for emitting a Blue (B) color light.

However, one pixel is by no means limited to a combination of the sub-pixels corresponding to the three primary colors of R, G, and B, and thus one pixel can also be structured by further adding a sub-pixel corresponding one color or sub-pixels corresponding to plural colors, respectively, to the sub-pixels corresponding to the three primary colors, respectively. More specifically, for example, for enhancement of the luminance, one pixel can also be structured by adding a sub-pixel for emitting a White (W) color light, or for increasing of a color reproduction image, one pixel can also be structured by adding at least one sub-pixel for emitting a complementary color light.

In the pixel array portion 30, for disposition of the pixels 30 of m in row×n in column, scanning lines 31₁ to 31ₘ and power source supply lines 32₁ to 32ₘ are wired so as to correspond to pixel rows, respectively, along a row direction (along a direction of disposition of the pixels 20 in the pixel rows). In addition thereto, for the disposition of the pixels 30 of m in row×n in column, signal lines 33₁ to 33ₙ are wired so as to correspond to pixel columns, respectively, along a column direction (along a direction of disposition of the pixels 20 in the pixel columns).

The scanning lines 31₁ to 31ₘ are connected to output terminals of corresponding rows of the write scanning circuit 40, respectively. The power source supply lines 31₁ to 31ₘ are connected to output terminals of corresponding rows of the power source supply scanning circuit 50, respectively. Also, the signal lines 33₁ to 33ₙ are connected to output terminals of corresponding columns of the signal outputting circuit 60, respectively.

The pixel array portion 30 is normally formed on a transparent insulating substrate such as a glass substrate. As a result, the organic EL display device 10 has a flat surface type (flat type) panel structure. The drive circuit for driving each of the pixels 20 in the pixel array portion 30 can be formed so as to be composed of either amorphous silicon TFTs or low-temperature poly silicon TFTs. When the drive circuit is composed of the low-temperature poly silicon TFTs, as shown in FIG. 6, all of the write scanning circuit 40, the power source supply scanning circuit 50, and the signal outputting circuit 60 can also be mounted onto a display panel (substrate) 70 composing the pixel array portion 30.

The write scanning circuit 40, for example, is composed of a shift register circuit for shifting (transferring) a start pulse sp one after another synchronously with a clock pulse ck. When a signal voltage of an image signal is written to the pixels 20 in the pixel array portion 30, the write scanning circuit 40 supplies write scanning signals WS (WS₁ to WSₘ) to the scanning lines 31 (31₁ to 31ₘ) one after another, thereby scanning the pixels 20 in the pixel array portion 30 in order in rows (line-sequential scanning).

The power source supply scanning circuit 50, for example, is composed of a shift register circuit for shifting (transferring) the start pulse sp one after another synchronously with the clock pulse ck. The power source supply scanning circuit 50 supplies power source electric potentials DS (DS₁ to DSₘ) each of which can be switched between a first power source electric potential V_{ccp} and a second power source electric potential Vᵢₙᵢ lower than the first power source electric potential V_{ccp} to the power source supply lines 32 (32₁ to 32ₘ), respectively, synchronously with the line-sequential scanning made by the write scanning circuit 40. As will be described later, by switching the power source electric potentials DS between the first power source electric potential V_{ccp} and the second power source electric potential Vᵢₙᵢ, the control for light emission/non-light emission of the pixels 20 is carried out.

The signal outputting circuit 60 selectively outputs a signal voltage V_{sig} of the image signal corresponding to luminance information supplied thereto from a signal supplying source (not shown) (hereinafter simply referred to as “a signal voltage” in some cases), and a reference voltage V_{ofs}. Here, the reference voltage V_{ofs} is an electric potential becoming a reference for the signal voltage V_{sig} of the video signal (for example, an electric potential corresponding to a black level of the image signal). Thus, the reference voltage V_{ofs} is used during threshold voltage correcting processing which will be described later.

The signal voltage V_{sig}/the reference voltage V_{ofs} outputted from the signal outputting circuit 60 is written to the pixels 20 in the pixel array portion 30 through the signal lines 33 (33₁ to 33ₙ) in pixel rows selected through the scanning made by the write scanning circuit 40. That is to say, the signal outputting circuit 60 adopts a drive form of the line-sequential writing in accordance with which the signal voltage V_{sig} is written in rows (lines).

### (Pixel Circuit)

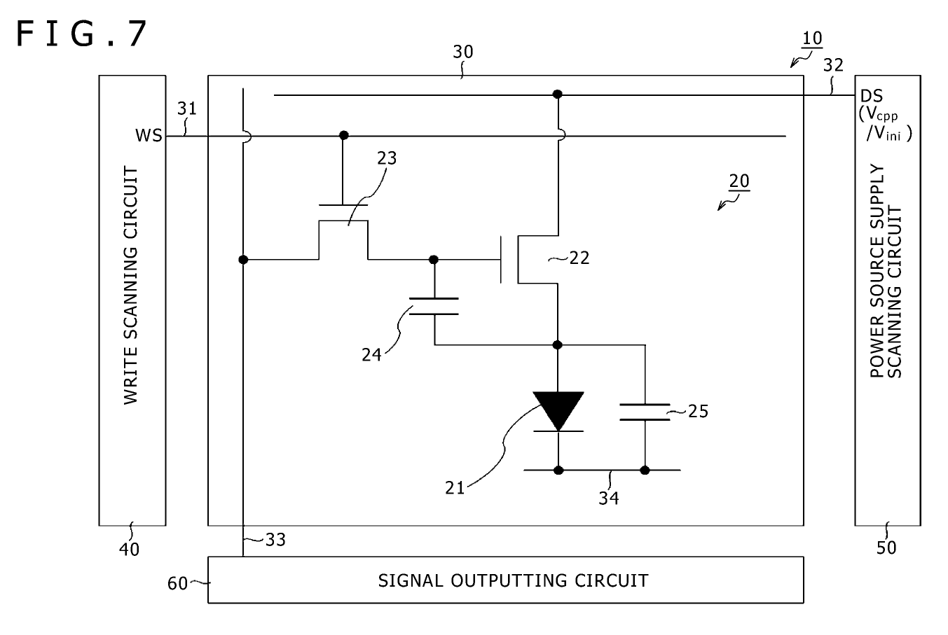

FIG. 7 is a circuit diagram showing an example of a concrete circuit configuration of the pixel (pixel circuit) 20. A light emitting portion of the pixel 20 is composed of an organic EL element 21 as a current drive type electrooptic element whose emission luminance is changed in accordance with a value of a current caused to flow through a device.

As shown in FIG. 7, the pixel 20 is composed of the organic EL element 21, and a drive circuit for driving the organic EL element 21 by causing a current to flow through the organic EL element 21. A cathode electrode of the organic EL element 21 is connected to a common power source supply line 34 which is wired (so-called solid wiring) so as to be common to all of the pixels 20.

The drive circuit for driving the organic EL element 21 has a configuration of having a drive transistor 22, a write transistor 23, a hold capacitor 24, and a subsidiary capacitor 25. An N-channel TFT can be used as each of the drive transistor 22 and the write transistor 23. However, a combination of the conductivity types of the drive transistor 22 and the write transistor 23 shown herein is merely an example, and thus the present disclosure is by no means limited to such a combination. In addition thereto, a wire connection relationship among the transistors, the hold capacitor, the organic EL element, and the like which will be described below is also by no means limited to such a form.

One electrode of a source electrode and a drain electrode of the drive transistor 22 is connected to an anode electrode of the organic EL element 21, and the other electrode of the source electrode and the drain electrode of the drive transistor 22 is connected to corresponding one of the power source supply lines 32 (32₁ to 32ₘ).

One electrode of a source electrode and a drain electrode of the write transistor 23 is connected to corresponding one of the signal lines 33 (33₁ to 33ₙ), and the other electrode of the source electrode and the drain electrode of the write transistor 23 is connected to a gate electrode of the drive transistor 22. In addition, a gate electrode of the write transistor 23 is connected to corresponding one of the scanning lines 31 (31₁ to 31ₘ).

In each of the drive transistor 22 and the write transistor 23, one electrode means a metallic wiring which is electrically connected to the source/drain region, and the other electrode means a metallic wiring which is electrically connected to the drain/source region. In addition, in accordance with an electric potential relationship between one electrode and the other electrode, one electrode becomes either the source electrode or the drain electrode, and the other electrode becomes either the drain electrode or the source electrode.

One electrode of the hold capacitor 24 is connected to a gate electrode of the drive transistor 22, and the other electrode thereof is connected to each of the other electrode of the drive transistor 22, and an anode electrode of the organic EL element 21.

One electrode of the subsidiary capacitor 25 is connected to the anode electrode of the organic EL element 21, and the other electrode thereof is connected to the common power source supply line 34. The subsidiary capacitor 25 is provided for the purpose of becoming subsidiary for an equivalent capacitance in order to compensate for an insufficient capacitance of the equivalent capacitance of the organic EL element 21, thereby increasing a write gain for the image signal for the hold capacitor 24.

In this case, although the other electrode of the subsidiary capacitor 25 is connected to the common power source supply line 34, a destination of connection of the other electrode of the subsidiary capacitor 25 is by no means limited to the common power source supply line 34, and thus all it takes is a node having a fixed electric potential set thereat. The other electrode of the subsidiary capacitor 25 is connected to the node having the fixed electric potential set thereat, whereby it is possible to attain the desired object such that the insufficient capacitance of the organic EL element 21 is compensated for and thus the write gain for the image signal for the hold capacitor 24 is increased.

In the pixel 20 having the configuration described above, the write transistor 23 becomes a conduction state in response to a write scanning signal WS at a High active which is applied from the write scanning circuit 40 to the gate electrode thereof through the scanning line 31. As a result, the write transistor 23 samples either a signal voltage V_{sig} of the image signal corresponding to the luminance information or a reference voltage V_{ofs} which is supplied thereto from the signal outputting circuit 60 through the signal line 33, and writes either the signal voltage V_{sig} or the reference voltage V_{ofs} thus sampled to the pixel 20. Either the signal voltage V_{sig} or the reference voltage V_{ofs} thus written is not only supplied to the gate electrode of the drive transistor 22, but also is held in the hold capacitor 24.

While the power source electric potential DS of corresponding one of the power source supply lines 32 (32₁ to 32ₘ) is held at a first power source electric potential V_{ccp}, one electrode of the drive transistor 22 serves as the drain electrode, and the other electric thereof serves as the source electrode, so that the drive transistor 22 is operated in a saturated region. As a result, the drive transistor 22 receives the supply of a current from the power source supply line 32 to emission-drive the organic EL element 21 through the current drive. More specifically, the drive transistor 22 is operated in the saturated region, whereby the drive transistor 22 supplies the drive current having a current value corresponding to the voltage value of the signal voltage V_{sig} held in the hold capacitor 24 to the organic EL element 21, and causes the organic EL element 21 to emit a light through the current drive.

In addition, when the power source electric potential DS is switched from the first power source electric potential V_{ccp} to the second power electric potential Vᵢₙᵢ, one electrode of the drive transistor 22 serves as the source electrode, and the other electrode thereof serves as the drain electrode, so that the drive transistor 22 is operated as a switching transistor. As a result, the drive transistor 22 stops the supply of the drive current to the organic EL element 21 to cause the organic EL element 21 to become a non-light emission state. That is to say, the drive transistor 22 also has a function as a transistor for controlling the light emission/non-light emission of the organic EL element 21.

By the switching operation of the drive transistor 22, a period of time (non-light emission period of time) is provided for which the organic EL element 21 is held in the non-light emission state, thereby making it possible to control a ratio (duty) of a light emission period of time to the non-light emission period of time in the organic EL element 21. Since by the duty control, it is possible to reduce residual image blurring following the light emission of the pixel over a period of time for one display frame, especially, it is possible to cause an image quality of a moving image to be more excellent.

Of the first and second power source electric potentials V_{ccp} and Vᵢₙᵢ which are selectively supplied from the power source supply scanning circuit 50 through the power source supply line 32, the first power source electric potential V_{ccp} is a power source electric potential with which the drive current for the light emission drive for the organic EL element 21 is supplied to the drive transistor 22. In addition, the second power source electric potential Vᵢₙᵢ is a power source electric potential with which a reverse bias voltage is applied to the organic EL element 21. The second power source electric potential Vᵢₙᵢ is set to an electric potential lower than the reference voltage V_{ofs}, for example, an electric potential lower than (V_{ofs}−Vₜₕ) where Vₜₕ is a threshold voltage of the drive transistor 22, preferably, an electric potential sufficiently lower than (V_{ofs}−Vₜₕ).

### [3-2. Basic Circuit Operation]

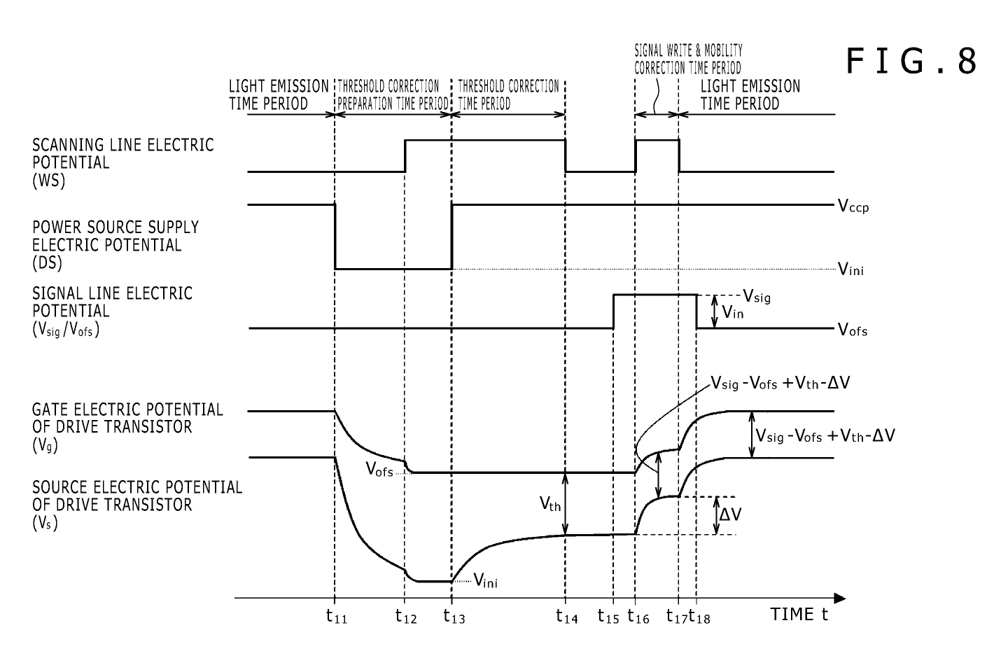

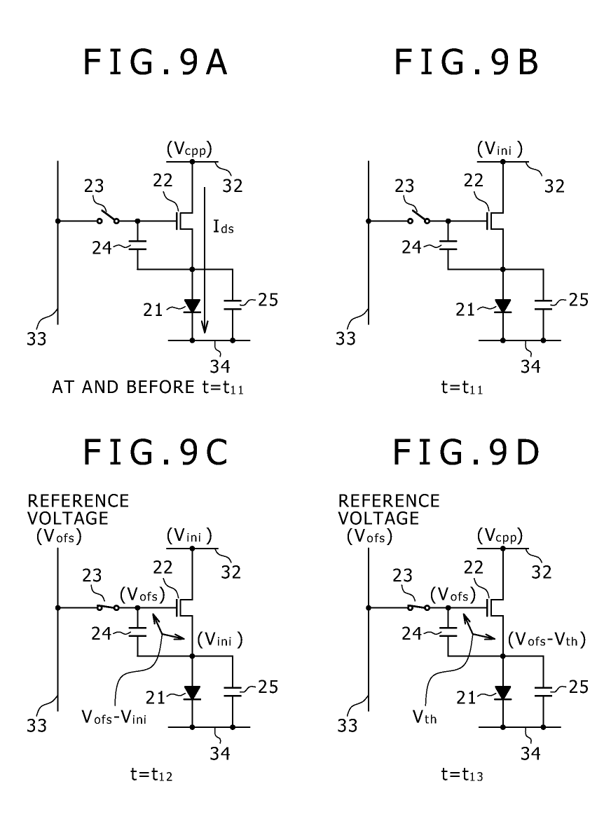

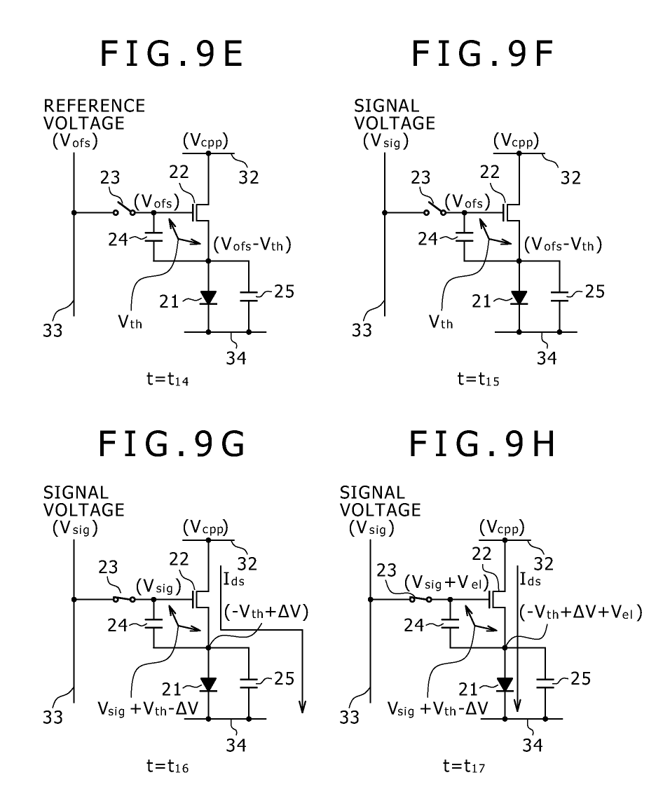

Subsequently, a basic circuit operation of the organic EL display device 10 having the configuration described above will be described based on a timing chart of FIG. 8 with reference to operation explanatory diagrams of FIGS. 9A to 9H. It is noted that in the operation explanatory diagrams of FIGS. 9A to 9H, for the sake of simplicity of the drawings, the write transistor 23 is illustrated in the form of a symbol of a switch.

The timing waveform chart of FIG. 8 shows changes in an electric potential (write scanning signal) WS of the scanning line 31, an electric potential (power source electric potential) DS of the power source supply line 32, an electric potential (V_{sig}/V_{ofs}) of the signal line 33, and a gate electric potential V_{g} and a source electric potential Vₛ of the drive transistor 22.

### (Period of Time for Light Emission in Preceding Display Frame)

In the timing waveform chart shown in FIG. 8, at and before a time t₁₁, there is shown a period of time for light emission of the organic EL element 21 in a preceding display frame. For the period of time for the light emission in the preceding display frame, the electric potential DS of the power source supply line 32 is held at a first power source electric potential (hereinafter referred to as “a high electric potential”) V_{ccp}, and the write transistor 23 is held in the non-conduction state.

At this time, the drive transistor 22 is designed so as to be operated in the saturated region. As a result, as shown in FIG. 9A, a drive current (drain-to-source current) I_{ds} corresponding to a gate-to-source voltage V_{gs} of the drive transistor 22 is supplied from the power source supply line 32 to the organic EL element 21 through the drive transistor 22. Therefore, the organic EL element 21 emits a light with a luminance corresponding to a current value of the drive current I_{ds}.

### (Period of Time for Preparation for Threshold Voltage Correction)

When it becomes the time t₁₁, the operation of the organic EL display device 10 enters a new display frame (current display frame) in the line-sequential scanning. Also, as shown in FIG. 9B, the electric potential DS of the power source supply line 32 is switched from the high electric potential V_{ccp} to a second power source electric potential which is sufficiently lower than (V_{ofs}−Vₜₕ) with respect to the reference voltage V_{ofs} of the signal line 33 (hereinafter referred to as “a low electric potential”).

Here, let Vₜₕₑₗ be a threshold voltage of the organic EL element 21, and let V_{cath} be an electric potential (cathode electric potential) of the common power source supply line 34. At this time, when the low electric potential Vᵢₙᵢ fulfills an electric potential relationship of Vᵢₙᵢ<(Vₜₕₑ₁+V_{cath}) since the source electric potential Vₛ of the drive transistor 22 becomes approximately equal to the low electric potential Vᵢₙᵢ, the organic EL element 21 becomes a reverse bias state to be quenched.

Next, at a time t₁₂, the electric potential WS of the scanning line 31 transits from the low electric potential side to the high electric potential side, whereby as shown in FIG. 9C, the write transistor 23 becomes the conduction state. Since at this time, a state is provided in which the reference electric potential V_{ofs} is supplied from the signal output circuit 60 to the signal line 33, the gate electric potential V_{g} of the drive transistor 22 becomes equal to the reference voltage V_{ofs}. In addition, the source electric potential Vₛ of the drive transistor 22 is equal to the electric potential which is sufficiently lower than the reference voltage V_{ofs}, that is, the low electric potential Vᵢₙᵢ.

At this time, the gate-to-source voltage V_{gs} of the drive transistor 22 becomes equal to (V_{ofs}−Vᵢₙᵢ). Here, since it is difficult to execute threshold correcting processing which will be described later unless (V_{ofs}−Vᵢₙᵢ) is larger than the threshold voltage Vₜₕ of the drive transistor 22, it is necessary to set an electric potential relationship of (V_{ofs}−Vᵢₙᵢ)>Vₜₕ.

As described above, the processing in which the gate electric potential V_{g} of the drive transistor 22 is fixed to the reference voltage V_{ofs}, and the source electric potential Vₛ thereof is fixed to (decided as) the low electric potential Vᵢₙᵢ, thereby carrying out initialization is processing for preparation (threshold voltage correcting preparation) before execution of threshold voltage correcting processing (threshold voltage correcting operation) which will be described later. Therefore, the reference voltage V_{ofs} and the low electric potential Vᵢₙᵢ become initialization electric potentials for the gate electric potential V_{g} and the source electric potential Vₛ of the transistor 22, respectively.

### (Period of Time for Threshold Voltage Correction)

Next, when at a time t₁₃, as shown in FIG. 9D, the electric potential DS of the power source supply line 32 is switched from the low electric potential Vᵢₙᵢ to the high electric potential V_{ccp}, the threshold voltage correcting processing is started in a state in which the gate electric potential V_{g} of the drive transistor 22 is held at the reference voltage V_{ofs}. That is to say, the source electric potential Vₛ of the drive transistor 22 is started to rise toward an electric potential obtained by subtracting the threshold voltage Vₜₕ of the drive transistor 22 from the gate electric potential V_{g} of the drive transistor 22.

In this case, for the sake of convenience, the processing for changing the source electric potential Vₛ of the drive transistor 22 toward an electric potential obtained by subtracting the threshold voltage Vₜₕ of the drive transistor 22 from an initialization electric potential V_{ofs} with the initialization electric potential V_{ofs} for the gate electric potential V_{g} of the drive transistor 22 as a reference is referred to as threshold voltage correcting processing. When the threshold voltage correcting processing proceeds, in a short time, the gate-to-source voltage V_{g} of the drive transistor 22 converges to the threshold voltage Vₜₕ of the drive transistor 22. A voltage corresponding to the threshold voltage Vₜₕ is held in the hold capacitor 24.

It is noted that in order that the current may be exclusively caused to flow through the hold capacitor 24 side, and thus may be prevented from being caused to flow through the organic EL element 21 side for a period of time for which the threshold voltage correcting processing is executed (a period of time for the threshold voltage correction), the electric potential V_{cath} of the common power source supply line 34 is set in such a way that the organic EL element 21 becomes a cut-off state.

Next, at a time t₁₄, the electric potential WS of the scanning line 31 transits from the high electric potential side to the low electric potential side, whereby as shown in FIG. 9E, the write transistor 23 becomes the non-conduction state. At this time, the gate electrode of the drive transistor 22 is electrically separated from the signal line 33 to become a floating state. However, since the gate-to-source voltage V_{gs} is equal to the threshold voltage Vₜₕ of the drive transistor 22, the drive transistor 22 concerned is held in a cut-off state. Therefore, the drain-to-source current I_{ds} is not caused to flow through the drive transistor 22.

### (Period of Time for Signal Write & Mobility Correction)

Next, at a time t₁₅, as shown in FIG. 9F, the electric potential of the signal line 33 is switched from the reference voltage V_{ofs} to the signal voltage V_{sig} of the image signal. Subsequently, at a time t₁₆, the electric potential WS of the scanning line 31 transits from the low electric potential side to the high electric potential side, whereby as shown in FIG. 9G, the write transistor 23 becomes the conduction state to sample the signal voltage V_{sig} of the image signal, thereby writing the signal voltage V_{sig} of the image signal thus sampled to the pixel 20.

By writing the signal voltage V_{sig} to the pixel 20 by the write transistor 23, the gate voltage V_{g} of the drive transistor 22 becomes equal to the signal voltage V_{sig}. Also, while the drive transistor 22 is driven by using the signal voltage V_{sig} of the image signal, the threshold voltage Vₜₕ of the drive transistor 22 is canceled by a voltage corresponding to the threshold voltage Vₜₕ held in the hold capacitor 24. The details of the principles of the threshold voltage canceling will be described later.

At this time, the organic EL element 21 is held in the cut-off state (in a high-impedance state). Therefore, the current (the drain-to-source current I_{ds}) which is caused to flow through the drive transistor 22 through the power source supply line 32 in accordance with the signal voltage V_{sig} of the image signal is caused to flow into both of an equivalent capacitance of the organic EL element 21, and the subsidiary capacitor 25. As a result, both of the equivalent capacitance of the organic EL element 21, and the subsidiary capacitor 25 are started to be charged with the electricity.

Both of the equivalent capacitance of the organic EL element 21, and the subsidiary capacitor 25 are charged with the electricity, whereby the source electric potential V_{S} of the drive transistor 22 rises with a lapse of time. At this time, the dispersion of the threshold voltages Vₜₕ of the drive transistors 22 in the pixels 20 is previously canceled, and thus the drain-to-source current I_{ds} of the drive transistor 22 depends on a mobility μ of the drive transistors 22. It is noted that the mobility μ of the drive transistors 22 is a mobility of a semiconductor thin film composing the channel of the drive transistors 22.

Here, it is assumed that a ratio of the hold voltage V_{gs} of the hold capacitor 24 to the signal voltage V_{sig} of the image signal, that is, a write gain G is 1 (ideal value). Then, the source electric potential V_{S} of the drive transistor 22 rises up to an electric potential of (V_{ofs}−Vₜₕ+ΔV), whereby the gate-to-source voltage V_{gs} of the drive transistors 22 becomes equal to (V_{sig}−V_{ofs}+Vₜₕ−ΔV).

That is to say, a rise amount ΔV of source electric potential V_{S} of the drive transistor 22 acts so as to be subtracted from the voltage (V_{sig}−V_{ofs}+Vₜₕ) held in the hold capacitor 24, in other words, so as to discharge the electric charges charged in the hold capacitor 24. In other words, the rise amount ΔV of source electric potential V_{S} is negatively fed back to the hold capacitor 24. Therefore, the rise amount ΔV of source electric potential V_{S} becomes a feedback amount in the negative feedback.

As described above, the feedback amount ΔV corresponding to the drain-to-source current I_{ds} caused to flow through the drive transistor 22 is negatively fed back to the gate-to-source voltage V_{gs}, whereby it is possible to cancel the dependency of the drain-to-source current I_{ds} of the drive transistor 22 on the mobility μ. This canceling processing is mobility correcting processing for correcting the disposition of the mobilities μ of the drive transistors 22 in the pixels 20.

More specifically, since the drain-to-source current I_{ds} becomes large as a signal amplitude Vᵢₙ (=V_{sig}−V_{ofs}) of the image signal written to the gate electrode of the drive transistor 22 is larger, an absolute value of the feedback amount ΔV of negative feedback becomes large accordingly. Therefore, there is executed the mobility correcting processing corresponding to an emission luminance level.

In addition, when the signal amplitude Vᵢₙ of the image signal is set constant, since the absolute value of the feedback amount ΔV of negative feedback becomes large as the mobility μ of the drive transistor 22 is larger, it is possible to remove the dispersion of the mobilities μ of the drive transistors 22 in the pixels 20. Therefore, the feedback amount ΔV of negative feedback can be the as a correction amount as well of mobility correcting processing. The details of the principles of the mobility correcting processing will be described later.

### (Period of Time for Light Emission)

Next, at a time t₁₇, the electric potential WS of the scanning line 31 transits from the high electric potential side to the low electric potential side, whereby as shown in FIG. 9H, the write transistor 23 becomes the non-conduction state. As a result, the gate electrode of the drive transistor 22 is electrically separated from the signal line 33 to become a floating state.

Here, while the gate electrode of the drive transistor 22 is held in the floating state, since the hold capacitor 24 is connected between the gate electrode and the source electrode of the drive transistor 22, the gate electric potential V_{g} is also changed in conjunction with the change in the source electric potential Vₛ of the drive transistor 22.

As has been described, the operation in which the gate electric potential V_{g} of the drive transistor 22 is changed in conjunction with the change in the source electric potential Vₛ of the drive transistor 22, in other words, the operation in which both of the gate electric potential V_{g} and the source electric potential V_{S} rise while the gate-to-source voltage V_{gs} held in the hold capacitor 24 is held is the bootstrap operation.

The gate electrode of the drive transistor 22 becomes the floating state, and at the same time, the drain-to-source current I_{ds} of the drive transistor 22 begins to be caused to flow through the organic EL element 21, whereby the anode electric potential of the organic EL element 21 rises in accordance with the drain-to-source current I_{ds}.

Also, since the drive current begins to be caused to flow through the organic EL element 21 when the anode electric potential of the organic EL element 21 exceeds (Vₜₕₑₗ+V_{cath}), the organic EL element 21 starts to emit the light. In addition, the rise in the anode electric potential of the organic EL element 21 is neither more nor less than the rise in the source electric potential V_{S} of the drive transistor 22. Also, when the source electric potential V_{S} of the drive transistor 22 rises, the gate electric potential V_{g} of the drive transistor 22 also rises in conjunction with that rise by the bootstrap operation.

At this time, when the bootstrap gain is assumed to be 1 (ideal value), a rise amount of gate electric potential V_{g} becomes equal to a rise amount of source electric potential V_{S}. For this reason, during the period of time for the light emission, the gate-to-source voltage V_{gs} of the drive transistor 22 is held at a constant value of (V_{sig}−V_{ofs}+Vₜₕ−ΔV). Also, at a time t₁₈, the electric potential of the signal line 33 is switched from the signal voltage V_{sig} of the image signal to the reference voltage V_{ofs}.

In a series of circuit operations described above, the processing operations for the threshold voltage correction preparation, the threshold voltage correction, the writing (signal writing) of the signal voltage V_{sig}, and the mobility correction are all carried out for the period of time for one horizontal scanning (1 H). In addition, the processing operations for the writing of the signal, and the mobility correction are carried out in parallel with each other for the period of time ranging from the time t₁₆ to the time t₁₇.

### [Division Threshold Voltage Correction]

Note that, although in this case, the description has been given by exemplifying the case where a driving method of executing the threshold voltage correcting processing only once is adopted, that driving method is merely an example, and thus the present disclosure is by no means limited to that driving method. For example, it is also possible to adopt the driving method of carrying out so-called threshold voltage correction for executing the divided threshold voltage correcting processing over plural periods of time for the horizontal scanning preceding the period of time for 1 H plural times in addition to the period of time for 1 H for which the threshold voltage correcting processing is executed together with both of the mobility correction and signal writing processing.

According to the driving method for the division threshold voltage correction, even when a time allocated as the period of time for 1 horizontal scanning is shortened by the multi-pixel promotion following the high-definition promotion, the sufficient time can be ensured over plural periods of time as the period of time for the threshold correction. Therefore, even when the time allocated as the period of time for 1 horizontal scanning is shortened, since the sufficient time can be ensured as the period of time for the threshold voltage correction, it is possible to reliably execute the threshold voltage correcting processing.

### [Principles of Threshold Voltage Cancel]

Now, a description will be given with respect to the principles of the threshold voltage cancel (that is, threshold voltage correction) for the drive transistor 22. The drive transistor 22 is operated as a constant current source because the drive transistor 22 is designed so as to be operated in the saturated region. As a result, a constant drain-to-source current (drive current) I_{ds} given by Expression (2) is supplied from the drive transistor 22 to the organic EL element 21:

I_{ds}=(½)×μ(W/L)C_{OX}(V_{gs}−Vₜₕ)² (2)

where W is a channel width of the drive transistor 22, L is a channel length of the drive transistor 22, and C_{OX} is a gate capacitance per unit area.

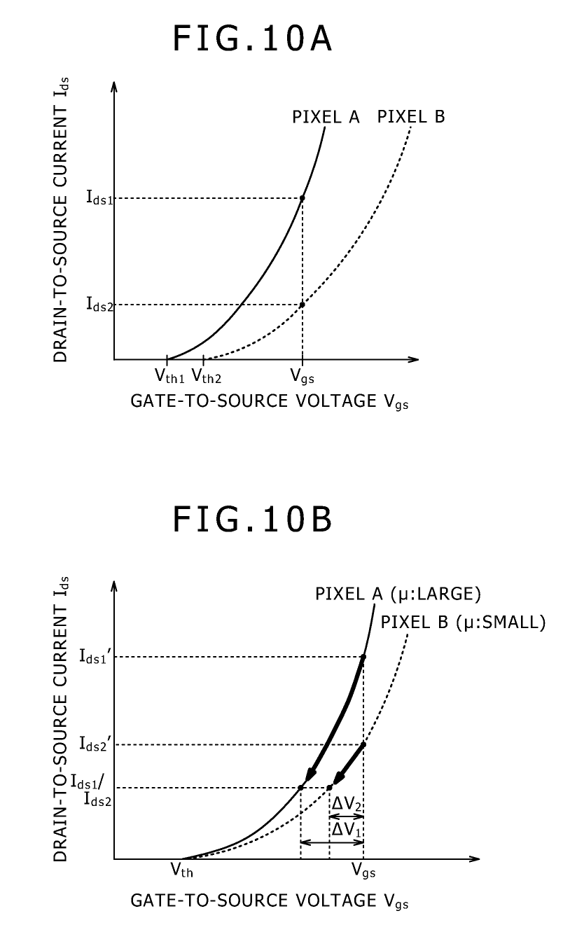

FIG. 10A shows characteristics of the drain-to-source current I_{ds} vs. the gate-to-source voltage V_{gs} in the drive transistor 22. As shown in the characteristic diagram of FIG. 10A, if the canceling processing (correction processing) for the dispersion of the threshold voltages Vₜₕ of the drive transistors 22 in the pixels 20 is not executed, when the threshold voltage Vₜₕ is equal to Vₜₕ₁, the drain-to-source current I_{ds} corresponding to the gate-to-source voltage V_{gs} becomes I_{ds1}.

On the other hand, when the threshold voltage Vₜₕ is equal to Vₜₕ₂ (Vₜₕ₂>Vₜₕ₁), the drain-to-source current I_{ds} corresponding to the gate-to-source voltage V_{gs} becomes equal to I_{ds2} (I_{ds2}<I_{ds1}). That is to say, when the threshold voltage Vₜₕ of the drain transistor 22 is changed, the drain-to-source current I_{ds} is changed accordingly even when the gate-to-source voltage V_{gs} is constant.

On the other hand, as described above, in the pixel (pixel circuit) 20 having the configuration described above, the gate-to-source voltage V_{gs} of the drive transistor 22 in the phase of the light emission is expressed by V_{gs}=(V_{sig}−V_{ofs}+Vₜₕ−ΔV). Therefore, when V_{gs}=(V_{sig}−V_{ofs}+Vₜₕ−ΔV) is substituted into Expression (2), the drain-to-source current I_{ds} is expressed by Expression (3):

I_{ds}=(½)×μ(W/L)C_{OX}(V_{sig}−V_{ofs}−ΔV)² (3)

That is to say, the term of the threshold voltage Vₜₕ of the drive transistor 22 is canceled, and thus the drain-to-source current I_{ds} supplied from the drive transistor 22 to the organic EL element 21 does not depend on the threshold voltage Vₜₕ of the drive transistor 22. As a result, even when the threshold voltage Vₜₕ of the drive transistor 22 is changed every pixel 20 owing to the dispersion of the manufacturing processes for the drive transistor 22, the temporal change, and the like, the emission luminance of the organic EL element 21 can be held constant because the drain-to-source current I_{ds} is not changed.

### [Principles of Mobility Correction]

Next, a description will now be given with respect to the principles of the mobility correction for the drive transistor 22. FIG. 10B shows characteristic curves in a state in which a pixel A having the drain transistor 22 whose mobility μ is relatively large, and a pixel B having the drain transistor 22 whose mobility μ is relatively small are compared with each other. When the drive transistor 22 is composed of a poly silicon thin film transistor and the like, it is difficult to avoid that the mobility μ is dispersed between the pixels like the pixel A and the Pixel B.

Let us consider the case where in a state in which the mobility μ is dispersed between the pixel A and the Pixel B, for example, the signal having voltage amplitudes Vᵢₙ (=V_{sig}−V_{ofs}) having the same level are written to the gate electrodes of the drive transistors 22 in the pixels A and B, respectively. In this case, when the mobility μ is not corrected at all, a large difference is generated between a drain-to-source current I_{ds1′} caused to flow through the pixel A having the larger mobility μ, and a drain-to-source current I_{ds2′} caused to flow through the pixel B having the smaller mobility μ. When a large difference is generated among the drain-to-source currents I_{ds} of the pixels 20 due to the dispersion of the mobilities μ of the drive transistors 22 in the pixels 20, the uniformity of the picture is impaired.

Here, as can be seen from Expression (1) described above as the transistor characteristic expression, the drain-to-source current I_{ds} becomes large with the increasing mobility μ. Therefore, the feedback amount ΔV in the negative feedback becomes large as the mobility μ is larger. As shown in FIG. 10B, a feedback amount ΔV₁ of the pixel A having the larger mobility μ becomes larger than a feedback amount ΔV₂ of the pixel B having the smaller mobility μ.

Then, the feedback amount ΔV corresponding to the drain-to-source current I_{ds} of the drive transistor 22 is negatively fed back to the gate-to-source voltage V_{gs} by executing the mobility correcting processing, whereby the large negative feedback is applied as the mobility μ is larger. As a result, it is possible to suppress the dispersion of the mobilities μ of the drive transistors 22 in the pixels 20.

Specifically, when in the pixel A having the larger mobility μ, the correction with the feedback amount ΔV₁ is carried out, the drain-to-source current I_{ds} largely drops from I_{ds1′} to I_{ds1}. On the other hand, since the feedback amount ΔV₂ of the pixel B having the smaller mobility μ is small, the drain-to-source current I_{ds} drops from I_{ds2′} to I_{ds2} and thus does not largely drop so much. As a result, since the drain-to-source current I_{ds1} of the pixel A, and the drain-to-source current I_{ds2} of the pixel B becomes approximately equal to each other, the dispersion of the mobilities μ of the drive transistors 22 in the pixels 20 is corrected.

The foregoing is summarized as follows. When there are the pixel A and the pixel B different in mobility μ from each other, the feedback amount ΔV₁ of the pixel A having the larger mobility μ becomes larger than the feedback amount ΔV₂ of the pixel B having the smaller mobility μ. In a word, in the pixel having the larger mobility μ, the feedback amount ΔV becomes large and a reduction amount of drain-to-source current I_{ds} becomes large.

Therefore, the feedback amount ΔV corresponding to the drain-to-source current I_{ds} of the drive transistor 22 is negatively fed back to the gate-to-source voltage V_{gs} by executing the mobility correcting processing, whereby current values of the drain-to-source currents I_{ds} of the pixels different in mobility μ from one another are uniformized. As a result, it is possible to correct the dispersion of the mobilities μ of the drive transistors 22 in the pixels 20. That is to say, the processing for negatively feeding the feedback amount (correction amount) ΔV corresponding to the current (the drain-to-source current I_{ds}) caused to flow through the drive transistor 22 back to the gate-to-source voltage V_{gs} of the drive transistor 22, that is, to the hold capacitor 24 becomes the mobility correcting processing. However, the threshold voltage correction and mobility correction as described above are not the essential operations in the present disclosure and, for example, the various kinds of correction and light emission as described above are by no means limited to such operations and timings.

In the organic EL display device 10 which has been described so far, the bootstrap circuit 87 according to the second embodiment of the present disclosure can be applied to the drive circuit (pixel circuit) for driving the organic EL element 21. In addition, the inverter circuit 80 of the first embodiment using the bootstrap circuit 87 of the second embodiment as described above can be applied to the scanning circuit of the third embodiment such as the write scanning circuit 40 or the power source supply scanning circuit 50. Hereinafter, a display device according to a fourth embodiment of the present disclosure, and a display device according to a fifth embodiment will be concretely described. In this case, in the display device of the fourth embodiment, the bootstrap circuit 87 of the second embodiment is applied to the drive circuit (pixel circuit). Also, in the display device of the fifth embodiment, the inverter circuit 80 of the first embodiment using the bootstrap circuit 87 of the second embodiment is applied to the scanning circuit of the third embodiment such as the write scanning circuit 40 or the power source supply scanning circuit 50.

### [3-3. Display Device Having Application to Pixel Circuit]

### Fourth Embodiment

As apparent from the description of the pixel circuit and circuit operation previously stated, in the pixel 20, the drive transistor 22 for driving the organic EL element 21 carries out the bootstrap operation during the driving for the organic EL element 21. That is to say, the hold capacitor 24 is connected between the gate electrode and the source electrode of the drive transistor 22, whereby the drive transistor 22 carries out the bootstrap operation in which during the rising of the source electric potential, the gate electric potential rises in accordance with the rising of the source electric potential.

The gain in the phase of the bootstrap operation, that is, the bootstrap gain is determined depending on the capacitance values of the parasitic capacitances parasitic in the gate electrode of the drive transistor 22, and the capacitance value of the hold capacitor 24 having one terminal connected to the gate electrode of the drive transistor 22. In the case of the pixel circuit including the drive transistor 22, the parasitic capacitances parasitic in the gate electrode of the drive transistor 22 include the parasitic capacitance between the gate electrode and the drain region of the drive transistor 22, the parasitic capacitance between the gate electrode and the source electrode of the drive transistor 22, and the parasitic capacitance between the gate electrode, and the source/drain region of the write transistor 23.

Also, of those parasitic capacitances, each of the capacitance values of the parasitic capacitance between the gate electrode and the drain region of the drive transistor 22, and the parasitic capacitance between the gate electrode and the source/drain region of the write transistor 23 is reduced, thereby making it possible to increase the bootstrap gain. This is apparent from Expression (1) described above.

Then, in the display device of the fourth embodiment, the asymmetric structure such that as shown in FIG. 4, the amount of overlap between the gate electrode and the drain region is smaller than that of overlap between the gate electrode and the source region is applied to at least the drive transistor 22. The asymmetric structure is applied, and the amount of overlap between the gate electrode and the drain region is made smaller than that of overlap on the source region side, preferably, made zero, whereby the capacitance value of the parasitic capacitance on the drain region side of the drive transistor 22 is reduced, preferably, made zero.

The capacitance value of the parasitic capacitance on the drain region side of the drive transistor 22 is reduced, preferably, made zero in such a way, whereby the bootstrap gain is increased all the more to come close to the ideal value, that is, 1 (100%) becomes the capacitance value concerned can be cut down. As a result, since the light emission state can be held while the difference between the threshold values Vₜₕ in the pixels 20 is maintained with respect to the gate-to-source voltage V_{gs} of the drive transistor 22, it is possible to suppress the dispersion of the luminances in the pixels 20. By the way, the dispersion of the luminances in the pixels 20 can be visually recognized in the form of a longitudinal streak or a transverse streak, a luminance nonuniformity or the like. Therefore, it is possible to suppress the dispersion of the luminances in the pixels 20, which results in that since it is possible to suppress the longitudinal streak or a transverse streak, a luminance nonuniformity or the like, it is possible to realize the enhancement of the uniformity of the picture.

[3-4. Display Device having Application to Scanning Circuit]

### Fifth Embodiment

In the display device according to the fifth embodiment of the present disclosure, the inverter circuit 80 of the first embodiment using (including) the bootstrap circuit 87 of the second embodiment described above is applied to each of the write scanning circuit 40 and the power source supply scanning circuit 50. Specifically, the inverter circuit 80 of the first embodiment is used as the inverter circuit composing each of the write scanning circuit 40 and the power source supply scanning circuit 50.

In manufacturing the drive circuit portion including the write scanning circuit 40 and the power source supply scanning circuit 50, composing the drive circuit portion concerned of the transistors having one type channels makes it possible to reduce the manufacturing cost as compared with the case where the drive circuit portion is composed of the transistors having two type channels. Therefore, for realizing the low cost promotion of the organic EL display device 10, as previously stated, preferably, the inverter circuit composing each of the write scanning circuit 40 and the power source supply scanning circuit 50 is composed of the transistors having one type channels.

### (Write Scanning Circuit)

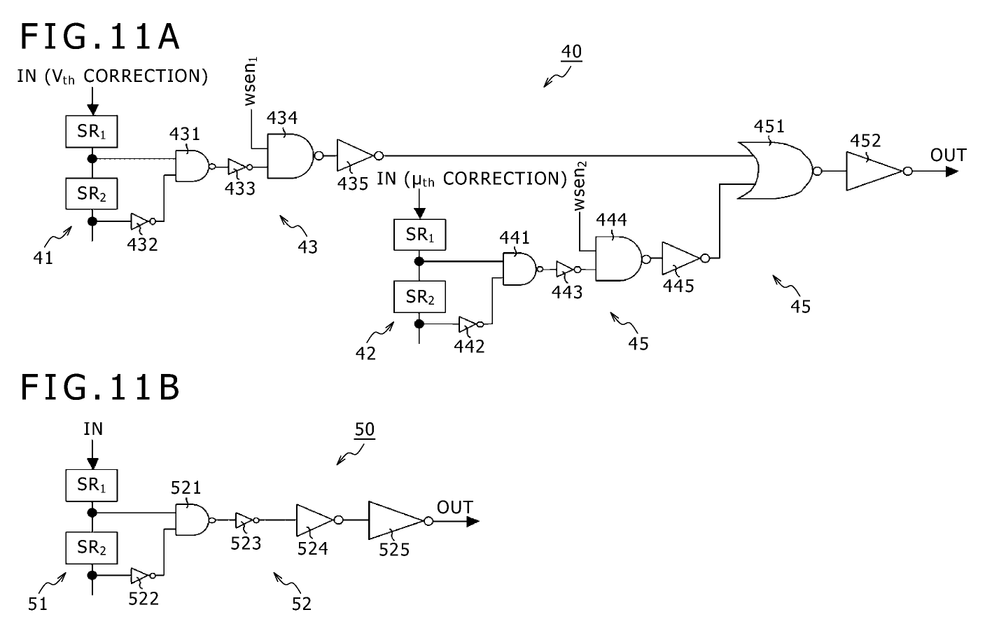

FIG. 11A is a logic circuit diagram showing a circuit configuration of the write scanning circuit 40. The write scanning circuit 40 in the display device of the fifth embodiment includes two shift register circuits 41 and 42 in order to generate the write scanning signal WS shown in FIG. 8. The shift register circuit 41 generates a scanning pulse for correction of the threshold voltage (Vₜₕ) (corresponding to the first-half pulse shown in FIG. 8). The shift register circuit 42 generates a scanning pulse for correction of the mobility a (corresponding to the second-half pulse shown in FIG. 8). Both of logic circuits 43 and 44 are disposed in a subsequent stage of both of the shift registers 41 and 42, and a common logic circuit 45 is disposed in a subsequent stage of both of the logic circuits 43 and 44.

The logic circuit 43 is composed of two NAND circuits 431 and 434, and three inverter circuits 432, 433, and 435. The NAND circuit 431 receives an output signal from a shift stage (transfer stage) SR₁ in a preceding stage of the shift register circuit 41 at one input terminal thereof, and receives a signal which is obtained by inverting an output signal from a shift stage SR₂ in subsequent stage in the inverter circuit 432 at the other input terminal thereof. The NAND circuit 434 receives a signal which is obtained by inverting an output signal from the NAND circuit 43 in the inverter circuit 433 at one input terminal thereof, and receives an enable signal wsen₁ at the other terminal thereof. An output signal from the NAND circuit 434 is supplied to the common logic circuit 45 in a subsequent stage.

The logic circuit 44 is composed of two NAND circuits 441 and 444, and three inverter circuits 442, 443, and 445. The NAND circuit 441 receives an output signal from the shift stage SR₁ in a preceding stage in the shift register circuit 42 at one input terminal thereof, and receives a signal which is obtained by inverting an output signal from the shift stage SR₂ in a subsequent stage in the inverter circuit 442 at the other input terminal thereof. The NAND circuit 444 receives a signal which is obtained by inverting an output signal from the NAND circuit 441 in the inverter circuit 443 at one input terminal thereof, and receives an enable signal wsen₂ at the other input terminal thereof. An output signal from the NAND circuit 444 is supplied to the common logic circuit 45 in a subsequent stage.

The common logic circuit 45 is composed of a NOR circuit 451 and an inverter circuit 452. The NOR circuit 451 receives two output signals from the logic circuits 43 and 44 in preceding stages at two input terminals thereof, respectively. An output signal from the common logic circuit 45 is supplied to the write scanning pulse (the electric potential of the scanning line) WS shown in FIG. 8 to corresponding one of the scanning lines 31 (31₁ to 31ₘ) of the pixel array portion 30 shown in FIG. 6. It is noted that the logic circuits 43 and 44, and the common logic circuit 45 are provided so as to correspond to the shift stages of the shift registers 41 and 42, respectively.

The inverter circuit 80 using (including) the bootstrap circuit 87 of the second embodiment described above can be used as each of the inverter circuits 432, 433, and 435 in the logic circuit 43, the inverter circuits 442, 443, and 445 in the logic circuit 44, and the inverter circuit 452 in the logic circuit 45 in the write scanning circuit 40 having the configuration as described above. In the case of the circuit configuration in which each of the shift registers 41 and 42 uses the inverter circuit described above, the inverter circuit 80 using (including) the bootstrap circuit 87 of the second embodiment described above can be used as the inverter circuit concerned. It is noted that in FIG. 11A, differences in size among the inverter circuits 432, 433, 435, 442, 443, 445, and 452 represent differences in size among the transistors composing those inverter circuits.

### (Power Source Supply Scanning Circuit)

FIG. 11B is a logic circuit diagram of the power source supply scanning circuit 50. The power source supply scanning circuit 50 in the display device according to the fifth embodiment has a configuration of having a shift register circuit 51 and a logic circuit 52. The logic circuit 52 is composed of a NAND circuit 521 and four inverter circuits 522 to 525, and is provided so as to correspond to a shift stage of the shift register circuit 51.

In the logic circuit 52, the NAND circuit 521 receives an input signal from a shift stage SR₁ in a preceding stage of the shift register circuit 51 at one input terminal thereof, and a signal which is obtained by inverting an input signal from a shift stage SR₂ in a subsequent stage in an inverter circuit 522 at the other input terminal thereof. An input signal from the NAND circuit 521 is supplied as the power source electric potential (power source supply electric potential) DS shown in FIG. 8 to correspond to one of the power source supply lines 32 (32₁ to 32ₘ) of the pixel array portion 30 shown in FIG. 6 through the inverter circuits 523, 524, and 525 in this order.

It is noted that an electric potential corresponding to the first power source electric potential V_{ccp} of the power source supply line electric potential DS is supplied as a positive power source electric potential to the inverter circuit 525 in the final stage, and an electric potential corresponding to the second power source electric potential Vᵢₙᵢ of the power source supply line electric potential DS is supplied as a negative power source electric potential to the inverter circuit 525.

The inverter circuit 80 using (including) the bootstrap circuit 87 of the second embodiment described above can be used as each of the inverter circuits 522 to 525 of the logic circuit 52. In the case of the circuit configuration in which the shift register 51 uses the inverter circuit, the inverter circuit 80 using (including) the bootstrap circuit 87 of the second embodiment described above can be used as the inverter circuit concerned. It is noted that in FIG. 11B, differences in size among the inverter circuits 522 to 525 represent differences in size among the transistors composing those inverter circuits.

The inverter circuit 80 using (including) the bootstrap circuit 87 of the second embodiment described above is used as the inverter circuit composing the write scanning circuit 40 and/or the power source supply scanning circuit 50, whereby it is possible to obtain the following operation and effects. That is to say, with regard to the transistor for carrying out the bootstrap operation, the source region and the drain region have the structure of being asymmetric with respect to the central line of the gate electrode, whereby as previously stated, the bootstrap gain is increased. Therefore, it is possible to more reliably output the signal having the full amplitude for a long period of time.

This means that in the write scanning circuit 40, a pulse signal having a desired pulse width can be obtained as the write scanning signal WS shown in FIG. 8 (that is, the scanning pulse for the correction for the threshold voltage, and the scanning pulse for the correction for the mobility). In addition, this means that in the power source supply scanning circuit 50, a pulse signal having a desired pulse width can be obtained as the power source supply line electric potential DS shown in FIG. 8.

Also, in the write scanning circuit 40, a pulse signal having a desired pulse width can be obtained as the write scanning signal WS, whereby it is possible to reliably execute both of the threshold voltage correcting processing and the mobility correcting processing. In particular, a correction time for the mobility correcting processing is determined depending on the pulse width of the scanning pulse for the mobility correction. Therefore, a pulse signal having a desired pulse width can be obtained as the scanning pulse concerned, whereby it is possible to more reliably execute the mobility correcting processing. In addition, in the power source supply scanning circuit 50, a pulse signal having a desired pulse width can be obtained as the power source supply line electric potential DS, whereby it is possible to more reliably carry out the control for the light emission/non-light emission of the pixel 20 in accordance with the switching between the first power source electric potential V_{ccp} and the second power source electric potential Vᵢₙᵢ of the power source electric potential DS concerned.

### [3-5. Modified Changes]

It is noted that although in this case, there has been exemplified the organic EL display device having the two transistors of the drive transistor 22 and the write transistor 23 as the pixel transistors, the present disclosure is by no means limited to the application to the organic EL display device concerned. Specifically, the present disclosure can also be applied to an organic EL display device including a pixel circuit having a transistor which is connected in series with the drive transistor in order to control light emission/non-light emission of the organic EL element, a pixel circuit including a transistor for selectively supplying the reference voltage V_{ofs} to the gate electrode of the drive transistor, or the like.

In addition, the present disclosure is by no means limited to the application to the organic EL display device, and thus can also be applied to all of display devices each using a current drive type electrooptic element (light emitting element) whose emission luminance is changed in accordance with a value of a current caused to flow through a device such as an inorganic Element, an LED element or a semiconductor laser device. In addition, the present disclosure can also be applied to all of display devices each having a configuration of using a scanning circuit and typified by a liquid crystal display device, a plasma display device, and the like.

### 4. Electronic Apparatus

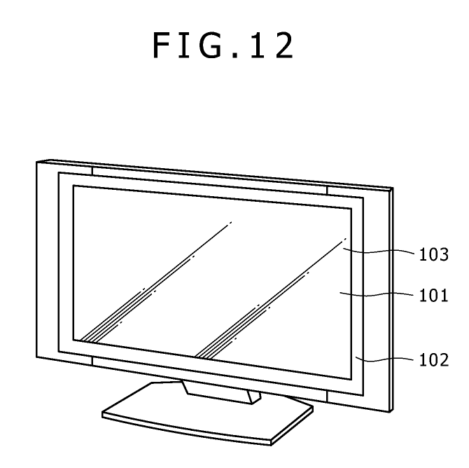

Any of the organic EL display devices according to the fourth and fifth embodiments of the present disclosure described above can be applied to the display portions (display devices), of electronic apparatuses in all of the fields, in each of which a video signal inputted to the electronic apparatus, or a video signal generated in the electronic apparatus is displayed in the form of an image or a video image. For example, any of the organic EL display devices according to the fourth and fifth embodiments of the present disclosure described above can be applied to the display portions of various kinds of electronic apparatuses, for example a television set, a digital camera, a notebook-size personal computer, mobile terminal equipment such as a mobile phone, and a video camera, as shown in FIG. 12 to FIGS. 16A to 16H, which will be described later.

As apparent from the description of the embodiments described above, in the case of the organic EL display device of the fourth embodiment in which the bootstrap circuit 87 of the second embodiment is applied to the drive circuit (pixel circuit), the longitudinal streak, the transverse streak, the luminance nonuniformity, and the like are suppressed, thereby making it possible to enhance the uniformity of the picture. On the other hand, in the case of the organic EL display device of the fifth embodiment in which the inverter circuit 80 of the first embodiment using the bootstrap circuit 87 of the second embodiment is applied to the scanning circuit of the third embodiment, it is possible to more reliably execute the correction processing and the like. Therefore, the display device of the present disclosure is used as each of the display portions of the electronic apparatuses in all of the fields, thereby making it possible to obtain a high-quality displayed image.

The display device of the present disclosure also includes an encapsulated display device having a mobile shape. As an example, a display module formed by sticking a facing portion made of a transparent glass or the like to a pixel array portion corresponds to the display device having the module shape. It is noted that a circuit portion, a Flexible Printed Circuit (FPC) board or the like for input/output of the signals from the outside to the pixel array portion may be provided in the display module.

### [4-1. Electronic Apparatus]

### Sixth Embodiment

An electronic apparatus according to a sixth embodiment of the present disclosure includes the organic EL display device 10 according to the fourth embodiment of the present disclosure. As described above, the organic EL display device 10 includes the pixel array portion 30 in which the pixels 20 each including the organic EL element (electrooptic element) 21 are disposed in a matrix, and the scanning circuit which scans the pixels 20 of the pixel array portion 30. In this case, each of the pixels 20 includes the drive transistor for driving corresponding one of the organic EL elements 22, and the hold capacitor 24 connected between the gate electrode of the drive transistor 22, and the source region of the drive transistor 22. Also, the drive transistor 22 has the structure in which the source region and the drain region have the structure of being asymmetric with respect to the central line O passing through the center of the gate electrode, and carries out the bootstrap operation in which the electric potential at the gate electrode is changed depending on the change in the electric potential at the source region.

### [4-2. Electronic Apparatus]

### Seventh Embodiment

An electronic apparatus according to a seventh embodiment of the present disclosure includes the organic EL display device 10 according to the fifth embodiment of the present disclosure. As described above, the organic EL display device 10 includes the pixel array portion 30 in which the pixels 20 each including the organic EL element (electrooptic element) 21 are disposed in a matrix, and the scanning circuit such as the write scanning circuit 40 or the power source supply scanning circuit 50 which scans the pixels 20 of the pixel array portion 30. In this case, the scanning circuit includes the transistor 85 including the gate electrode, and the source and drain regions. Also, the hold capacitor 86 is connected between the gate electrode and the source region. The transistor 85 carries out the bootstrap operation in which the electric potential at the gate electrode is changed depending on the change in an electric potential at the source region, and the transistor 82 having the same conductivity type as that of the transistor 85 and connected in series with the transistor 85. In this case, the transistor 85 has the structure in which the source region and the drain region have the structure of being asymmetric with respect to the central line O passing through the center of the gate electrode. Also, the polarity of the signal inputted to the gate terminal of the transistor 82 is inverted and the resulting signal having the inverted polarity is outputted.

### [4-3. Examples of Application]

Hereinafter, examples of application in each of which the organic EL display device according to the fourth embodiment of the present disclosure is applied to a display portion of the electronic apparatus according to the sixth embodiment of the present disclosure will be described with reference to FIG. 12 to FIGS. 16A to 16G, respectively.

### (First Examples of Application)

FIG. 12 is a perspective view showing an external appearance of a television set as a first example of application to which the organic EL display device of the fourth embodiment is applied. The television set according to the first example of application, for example, includes an image display screen portion 101 composed of a front panel 102, a filter glass 103, and the like. In this case, the television set is manufactured by using of the organic EL display device of the fourth embodiment described above as the image display screen portion 101.

### (Second Example of Application)

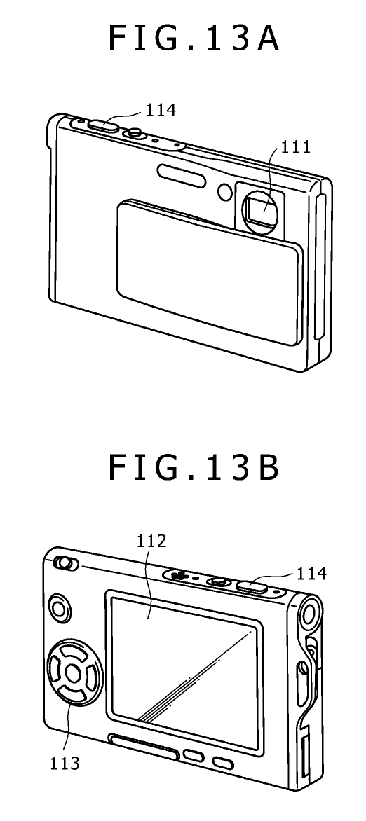

FIGS. 13A and 13B are respectively perspective views showing respective external appearances of a digital camera as a second example of application to which the organic EL display device of the fourth embodiment described above is applied. Here, FIG. 13A is a perspective view when the digital camera is viewed from a front side, and FIG. 13B is a perspective view when the digital camera is viewed from a back side. The digital camera according to the second example of application includes a light emitting portion 111 for flash, a display portion 112, a menu switch 113, a shutter button 114, and the like. In this case, the digital camera is manufactured by using the organic EL display device of the fourth embodiment described above as the display portion 112.

### (Third Example of Application)

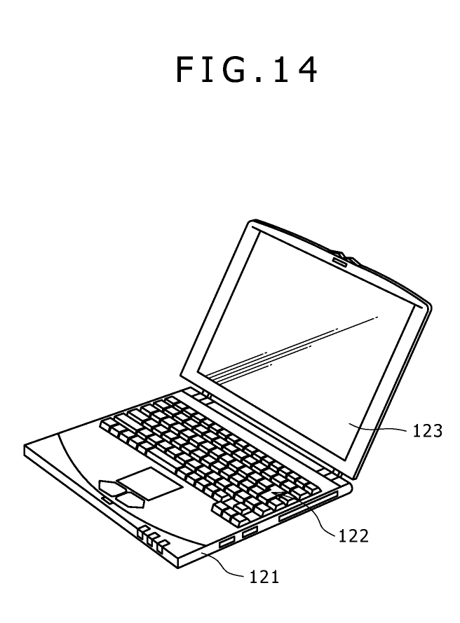

FIG. 14 is a perspective view showing an external appearance of a notebook-size personal computer as a third example of application to which the organic EL display device of the fourth embodiment described above is applied. The notebook-size personal computer according to the third example of application includes a main body 121, a keyboard 122 which is manipulated when characters or the like are inputted, a display portion 123 for displaying thereon an image, and the like. In this case, the notebook-size personal computer is manufactured by using the organic EL display device of the fourth embodiment described above as the display portion 123.

### (Fourth Example of Application)

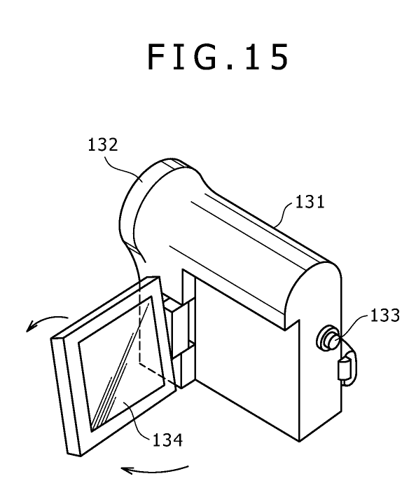

FIG. 15 is a perspective view showing an external appearance of a video camera as a fourth example of application to which the organic EL display device of the fourth embodiment described above is applied. The video camera includes a main body portion 131, a lens 132 which captures an image of a subject and which is provided on a side surface directed forward, a start/stop switch 133 which is manipulated when an image of a subject is captured, a display portion 134, and the like. In this case, the video camera is manufactured by using the organic EL display device of the fourth embodiment described above as the display portion 134.

### (Fifth Example of Application)

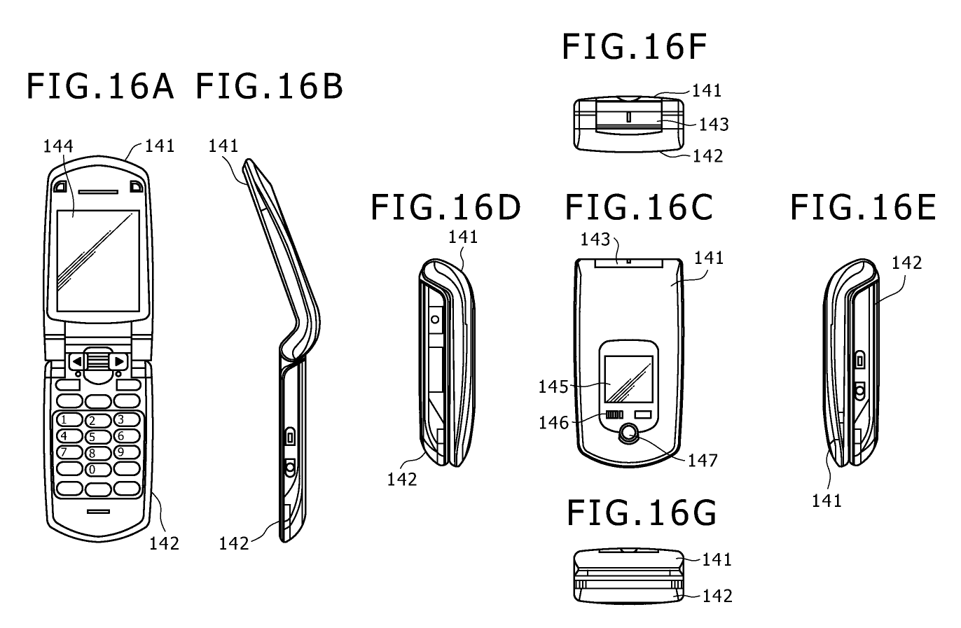

FIGS. 16A to 16G are respectively views showing respective external appearances of mobile terminal equipment, for example, a mobile phone as a fifth example of application to which the organic EL display device of the fourth embodiment described above is applied. Here, FIGS. 16A to 16G are respectively a front view of the mobile phone as the fifth example of application, in an open state, to which the organic EL display device of the fourth embodiment is applied, a side elevational view thereof in the open state, a front view thereof in a close state, a left side elevational view thereof in the close state, a right side elevational view thereof in the close state, a top plan view thereof in the close state, and a bottom view thereof in the close state. The mobile phone according to the fifth example of application includes an upper chassis 141, a lower chassis 142, a coupling portion (a hinge portion in this case) 143, a display portion 144, a sub-display portion 145, a picture light 146, a camera 147, and the like. In this case, the mobile phone is manufactured by using the organic EL display device of the fourth embodiment described above as the display portion 144 and/or the sub-display portion 145.

It is noted that although in each of the first to fifth examples of application, the organic EL display device of the fourth embodiment described above is applied to the display portion of the electronic apparatus according to the sixth embodiment of the present disclosure, the organic EL display device of the fourth embodiment can also be applied to the display portion of the electronic apparatus according to the seventh embodiment of the present disclosure.

In addition, it is noted that for each of the first to fifth examples of application, the organic EL display device of the fifth embodiment may also be applied to any of the display portion of the electronic apparatus according to the sixth embodiment of the present disclosure, and the display portion of the electronic apparatus according to the seventh embodiment of the present disclosure.

### 5. Constitutions of the Present Disclosure

It is noted that the present disclosure can adopt the following constitutions.

(1) A bootstrap circuit including: a transistor; and a capacitor connected between a gate electrode of the transistor, and one of source and drain regions of the transistor, the bootstrap circuit serving to carry out a bootstrap operation in which an electric potential at the gate electrode is changed depending on a change in an electric potential at the one of the source and drain regions, in which the transistor has a structure in which the source region and the drain region have a structure of being asymmetric with respect to a line passing through a center of the gate electrode.

(2) The bootstrap circuit described in the paragraph (1), in which in the transistor, an amount of overlap between the gate electrode and the one of the source and drain regions, and an amount of overlap between the gate electrode and the other of the source and drain regions are different from each other.

(3) The bootstrap circuit described in the paragraph (2), in which the amount of overlap between the gate electrode and the one of the source and drain regions is smaller than the amount of overlap between the gate electrode and the other of the source and drain regions.

(4) The bootstrap circuit described in the paragraph (3), in which the amount of overlap between the gate electrode and the one of the source and drain regions is zero.

(5) The bootstrap circuit described in any one of the paragraphs (1) to (4), in which one of source and drain regions of at least one transistor is connected to the gate electrode side of the transistor; and

in the at least one transistor, the source region and the drain region have a structure of being asymmetric with respect to a line passing through a gate electrode thereof.

(6) The bootstrap circuit described in the paragraph (5), in which in the at least one transistor, an amount of overlap between the gate electrode and one of the source and drain regions, and an amount of overlap between the gate electrode and the other of the source and drain regions are different from each other.

(7) The bootstrap circuit described in the paragraph (6), in which in the at least one transistor, the amount of overlap between the gate electrode and the one of the source and drain regions is smaller than that of overlap between the gate electrode and the other of the source and drain regions.

(8) The bootstrap circuit described in the paragraph (7), in which in the at least one transistor, the amount of overlap between the gate electrode and the one of the source and drain regions is zero.

(9) An inverter circuit including: a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and the regions, and a second transistor having the same conductivity type as that of the first transistor and connected in series with the first transistor, in which the first transistor has a structure in which the source region and the drain region have a structure of being asymmetric with respect to a line passing through a center of the gate electrode; and a polarity of a signal inputted to the gate electrode of the second transistor is inverted and a resulting signal having an inverted polarity is outputted.

(10) The inverter circuit described in the paragraph (9), further including a third transistor whose gate electrode and the second transistor are connected so as to be common to each other, and whose one of source and drain regions is connected to the gate electrode of the first transistor,

in which in the third transistor, the source region and the drain region have a structure of being asymmetric with respect to a line passing through a center of the gate electrode.

(11) The inverter circuit described in the paragraph (10), in which in the third transistor, an amount of overlap between the gate electrode and one of the source and drain regions, and an amount of overlap between the gate electrode and the other of the source and drain regions are different from each other.

(12) The inverter circuit described in the paragraph (11), in which in the third transistor, the amount of overlap between the gate electrode and one of the source and drain regions is smaller than that of the amount of overlap between the gate electrode and the other of the source and drain regions.

(13) The inverter circuit described in any one of the paragraphs (9) to (12), further including a voltage setting portion for setting a voltage developed across the gate electrode, and the one of the source and drain regions of the first transistor between which the capacitor is connected to a predetermined voltage prior to the bootstrap operation by the first transistor,

in which the voltage setting portion includes a control transistor whose one of source and drain regions is connected to the gate electrode of the first transistor, and which selectively supplies the predetermined voltage to the gate electrode of the first transistor; and

in the control transistor, the source region and the drain region have a structure of being asymmetric with respect to a line passing through a center of the gate electrode thereof.

(14) The inverter circuit described in the paragraph (13), in which in the control transistor, an amount of overlap between the gate electrode and the one of the source and drain regions, and an amount of overlap between the gate electrode and the other of the source and drain regions ar5e different from each other.

(15) The inverter circuit described in the paragraph (14), in which in the control transistor, the amount of overlap between the gate electrode and the one of the source and drain regions is smaller than that of overlap between the gate electrode and the other of the source and drain regions.

(16) A scanning circuit including: an inverter circuit, the inverter circuit including:

a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions; and

a second transistor having the same conductivity type as that of the first transistor and connected in series with the first transistor,

in which the first transistor has a structure in which the source region and the drain region have a structure of being asymmetric with respect to a line passing through a center of the gate electrode; and a polarity of a signal inputted to the gate electrode of the second transistor is inverted and a resulting signal having an inverted polarity is outputted.

(17) A display device including:

a pixel array portion in which pixels each including an electrooptic element are disposed in a matrix; and

a scanning circuit scanning the pixels of the pixel array portion, the scanning circuit including: an inverter circuit,

the inverter circuit including:

a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions; and

a second transistor having the same conductivity type as that of the first transistor and connected in series with the first transistor,

in which the first transistor has a structure in which the source region and the drain region have a structure of being asymmetric with respect to a line passing through a center of the gate electrode; and a polarity of a signal inputted to the gate electrode of the second transistor is inverted and a resulting signal having an inverted polarity is outputted.

(18) A display device including:

a pixel array portion in which pixels each including an electrooptic element are disposed in a matrix; and

a scanning circuit scanning the pixels of the pixel array portion,

in which each of the pixels includes:

a drive transistor driving corresponding one of the electrooptic elements; and

a capacitor connected between a gate electrode of the drive transistor, and one of source and drain regions of the drive transistor; and

the drive transistor has a structure in which the source region and the drain region have a structure of being asymmetric with respect to a line passing through a center of the gate electrode, and serves to carry out a bootstrap operation in which an electric potential at the gate electrode is changed depending on a change in an electric potential at the one of the source region and the drain region.

(19) An electronic apparatus including: a display device,

the display device including: a pixel array portion in which pixels each including an electrooptic element are disposed in a matrix; and a scanning circuit scanning the pixels of the pixel array portion,

the scanning circuit including: an inverter circuit,

the inverter circuit including:

a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions; and a second transistor having the same conductivity type as that of the first transistor and connected in series with the first transistor,

in which the first transistor has a structure in which the source region and the drain region have a structure of being asymmetric with respect to a line passing through a center of the gate electrode; and a polarity of a signal inputted to the gate electrode of the second transistor is inverted and a resulting signal having an inverted polarity is outputted.

(20) An electronic apparatus including: a display device,

the display device including: a pixel array portion in which pixels each including an electrooptic element are disposed in a matrix; and a scanning circuit scanning the pixels of the pixel array portion,

in which each of the pixels includes:

a drive transistor driving corresponding one of the electrooptic elements; and

a capacitor connected between a gate electrode of the drive transistor, and one of source and drain regions of the drive transistor; and

the drive transistor has a structure in which the source region and the drain region have a structure of being asymmetric with respect to a line passing through a center of the gate electrode, and serves to carry out a bootstrap operation in which an electric potential at the gate electrode is changed depending on a change in an electric potential at the one of the source region and the drain region.

The present disclosure contains subject matter related to that disclosed in Japanese Priority Patent Application JP 2011-113047 filed in the Japan Patent Office on May 20, 2011, the entire content of which is hereby incorporated by reference.

It should be understood by those skilled in the art that various modifications, combinations, sub-combinations and alterations may occur depending on design requirements and other factors in so far as they are within the scope of the appended claims or the equivalents thereof.

What is claimed is:

1. A bootstrap circuit comprising:
a transistor; and
a capacitor connected between a gate electrode of the transistor, and one of source and drain regions of the transistor,
the bootstrap circuit serving to carry out a bootstrap operation in which an electric potential at the gate electrode is changed depending on a change in an electric potential at the one of the source and drain regions,
in which the transistor has a structure in which the source region and the drain region have a structure of being asymmetric with respect to a line passing through a center of the gate electrode.

2. The bootstrap circuit according to claim 1, wherein in the transistor, an amount of overlap between the gate electrode and the one of the source and drain regions, and an amount of overlap between the gate electrode and the other of the source and drain regions are different from each other.

3. The bootstrap circuit according to claim 2, wherein the amount of overlap between the gate electrode and the one of the source and drain regions is smaller than the amount of overlap between the gate electrode and the other of the source and drain regions.

4. The bootstrap circuit according to claim 3, wherein the amount of overlap between the gate electrode and the one of the source and drain regions is zero.

5. The bootstrap circuit according to claim 1, wherein one of source and drain regions of at least one transistor is connected to the gate electrode side of the transistor, and
in the at least one transistor, the source region and the drain region have a structure of being asymmetric with respect to a line passing through a gate electrode thereof.

6. The bootstrap circuit according to claim 5, wherein in the at least one transistor, an amount of overlap between the gate electrode and one of the source and drain regions, and an amount of overlap between the gate electrode and the other of the source and drain regions are different from each other.

7. The bootstrap circuit according to claim 6, wherein in the at least one transistor, the amount of overlap between the gate electrode and the one of the source and drain regions is smaller than that of overlap between the gate electrode and the other of the source and drain regions.

8. The bootstrap circuit according to claim 7, wherein in the at least one transistor, the amount of overlap between the gate electrode and the one of the source and drain regions is zero.

9. An inverter circuit, comprising:
a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions; and
a second transistor having the same conductivity type as that of the first transistor and connected in series with the first transistor,
wherein the first transistor has a structure in which the source region and the drain region have a structure of being asymmetric with respect to a line passing through a center of the gate electrode, and
a polarity of a signal inputted to the gate electrode of the second transistor is inverted and a resulting signal having an inverted polarity is outputted.

10. The inverter circuit according to claim 9, further comprising:
a third transistor whose gate electrode and the second transistor are connected so as to be common to each other, and whose one of source and drain regions is connected to the gate electrode of the first transistor,
wherein in the third transistor, the source region and the drain region have a structure of being asymmetric with respect to a line passing through a center of the gate electrode.

11. The inverter circuit according to claim 10, wherein in the third transistor, an amount of overlap between the gate electrode and one of the source and drain regions, and an amount of overlap between the gate electrode and the other of the source and drain regions are different from each other.

12. The inverter circuit according to claim 11, wherein in the third transistor, the amount of overlap between the gate electrode and the one of the source and drain regions is smaller than that of the amount of overlap between the gate electrode and the other of the source and drain regions.

13. The inverter circuit according to claim 9, further comprising:
a voltage setting portion setting a voltage developed across the gate electrode, and the one of the source and drain regions of the first transistor between which the capacitor is connected to a predetermined voltage prior to the bootstrap operation by the first transistor,
wherein the voltage setting portion includes a control transistor whose one of source and drain regions is connected to the gate electrode of the first transistor, and which selectively supplies the predetermined voltage to the gate electrode of the first transistor, and
in the control transistor, the source region and the drain region have a structure of being asymmetric with respect to a line passing through a center of the gate electrode thereof.

14. The inverter circuit according to claim 13, wherein in the control transistor, an amount of overlap between the gate electrode and the one of the source and drain regions, and an amount of overlap between the gate electrode and the other of the source and drain regions are different from each other.

15. The inverter circuit according to claim 14, wherein in the control transistor, the amount of overlap between the gate electrode and the one of the source and drain regions is smaller than that of overlap between the gate electrode and the other of the source and drain regions.

16. A scanning circuit comprising an inverter circuit, the inverter circuit including
a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions, and
a second transistor having the same conductivity type as that of the first transistor and connected in series with the first transistor,
wherein the first transistor has a structure in which the source region and the drain region have a structure of being asymmetric with respect to a line passing through a center of the gate electrode, and
a polarity of a signal inputted to the gate electrode of the second transistor is inverted and a resulting signal having an inverted polarity is outputted.

17. A display device, comprising:
a pixel array portion in which pixels each including an electrooptic element are disposed in a matrix; and
a scanning circuit scanning the pixels of the pixel array portion,
the scanning circuit including an inverter circuit, the inverter circuit including
a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions, and
a second transistor having the same conductivity type as that of the first transistor and connected in series with the first transistor,
wherein the first transistor has a structure in which the source region and the drain region have a structure of being asymmetric with respect to a line passing through a center of the gate electrode, and
a polarity of a signal inputted to the gate electrode of the second transistor is inverted and a resulting signal having an inverted polarity is outputted.

18. An display device, comprising:
a pixel array portion in which pixels each including an electrooptic element are disposed in a matrix; and
a scanning circuit scanning the pixels of the pixel array portion,
wherein each of the pixels includes
a drive transistor driving corresponding one of the electrooptic elements, and
a capacitor connected between a gate electrode of the drive transistor, and one of source and drain regions of the drive transistor, and
the drive transistor has a structure in which the source region and the drain region have a structure of being asymmetric with respect to a line passing through a center of the gate electrode, and serves to carry out a bootstrap operation in which an electric potential at the gate electrode is changed depending on a change in an electric potential at the one of the source region and the drain region.

19. An electronic apparatus comprising a display device, the display device including
a pixel array portion in which pixels each including an electrooptic element are disposed in a matrix, and
a scanning circuit scanning the pixels of the pixel array portion,
the scanning circuit including an inverter circuit, the inverter circuit including
a first transistor including a gate electrode, and source and drain regions, a capacitor being connected between the gate electrode and one of the source and drain regions, the first transistor serving to carry out a bootstrap operation in which an electric potential at the gate electrode is changed depending on a change in an electric potential at the one of the source and drain regions, and
a second transistor having the same conductivity type as that of the first transistor and connected in series with the first transistor,
wherein the first transistor has a structure in which the source region and the drain region have a structure of being asymmetric with respect to a line passing through a center of the gate electrode, and
a polarity of a signal inputted to the gate electrode of the second transistor is inverted and a resulting signal having an inverted polarity is outputted.

20. An electronic apparatus comprising a display device, the display device including
a pixel array portion in which pixels each including an electrooptic element are disposed in a matrix, and
a scanning circuit scanning the pixels of the pixel array portion,
wherein each of the pixels includes
a drive transistor driving corresponding one of the electrooptic elements, and
a capacitor connected between a gate electrode of the drive transistor, and one of source and drain regions of the drive transistor, and
the drive transistor has a structure in which the source region and the drain region have a structure of being asymmetric with respect to a line passing through a center of the gate electrode, and serves to carry out a bootstrap operation in which an electric potential at the gate electrode is changed depending on a change in an electric potential at the one of the source region and the drain region.
